(19) United States
(12) Patent Application Publication
(10) Pub. No.: US 2024/0178274 A1
(43) Pub. Date: May 30, 2024

(54) INTEGRATED CIRCUIT DEVICE

(71) Applicant: SAMSUNG ELECTRONICS CO., LTD., SUWON-SI (KR)

(72) Inventors: Gunho Jo, Suwon-si (KR); Heesub Kim, Suwon-si (KR); Seung Hyun Lim, Suwon-si (KR); Bomi Kim, Suwon-si (KR); Eunho Cho, Suwon-si (KR)

(21) Appl. No.: 18/366,922

(22) Filed: Aug. 8, 2023

(30) Foreign Application Priority Data
Nov. 30, 2022 (KR) 10-2022-0165108

(51) Int. Cl. H01L 29/06; H01L 27/092; H01L 29/423; H01L 29/66; H01L 29/775

(52) U.S. Cl. CPC H01L 29/0673; H01L 27/092; H01L 29/42392; H01L 29/66545; H01L 29/775

(57) ABSTRACT

An integrated circuit device includes a first fin-type active region and a second fin-type active region, a device isolation film adjacent to each of the first and second fin-type active regions, a first gate line on the first fin-type active region, a second gate line on the second fin-type active region, and a gate cut insulating pattern separating the first and second gate lines, wherein the device isolation film includes a first local isolation portion and a second local isolation portion, which are separating the first fin-type active region from the second fin-type active region to be apart from each other with the gate cut insulating pattern therebetween.

### CROSS-REFERENCE TO RELATED APPLICATION

This application is based on and claims priority under 35 U.S.C. § 119 to Korean Patent Application No. 10-2022-0165108, filed on Nov. 30, 2022, in the Korean Intellectual Property Office, the disclosure of which is incorporated by reference herein in its entirety.

### BACKGROUND

The inventive concept relates to an integrated circuit device, and more particularly, to an integrated circuit device including a field-effect transistor.

Along with the decreasing sizes of integrated circuit devices, there is a need to increase the degree of integration of field-effect transistors on substrates, and thus, horizontal nanosheet field-effect transistors (hNSFETs), which include a plurality of horizontal nanosheets stacked on the same layout area, have been developed. As integrated circuit devices have increasing degrees of integration and decreasing sizes, there is a need to develop a new structure capable of improving the performance and reliability of nanosheet field-effect transistors.

### SUMMARY

The inventive concept provides an integrated circuit device, which allows the possibility of the generation of process defects in a fabrication process of the integrated circuit device to be removed, and which allows a nanosheet field-effect transistor therein to provide stable performance and improved reliability.

According to an aspect of the inventive concept, there is provided an integrated circuit device including a first fin-type active region and a second fin-type active region, which extend parallel to each other in a first horizontal direction on a substrate and are spaced apart from each other in a second horizontal direction intersecting with the first horizontal direction, a device isolation film adjacent to each of the first fin-type active region and the second fin-type active region, a first gate line arranged on the first fin-type active region and extending lengthwise in the second horizontal direction, a second gate line arranged on the second fin-type active region and separated from the first gate line in the second horizontal direction and extending lengthwise along an extension line of the first gate line in the second horizontal direction, and a gate cut insulating pattern between the first gate line and the second gate line, wherein the device isolation film includes a first local isolation portion and a second local isolation portion, which are arranged between the first fin-type active region and the second fin-type active region, the first local isolation portion and the second local isolation portion being apart from each other in the second horizontal direction with the gate cut insulating pattern therebetween.

According to another aspect of the inventive concept, there is provided an integrated circuit device including a plurality of fin-type active regions protruding in a vertical direction from a substrate and extending parallel to each other in a first horizontal direction to be apart from each other in a second horizontal direction that intersects with the first horizontal direction, a device isolation film covering both sidewalls of each of the plurality of fin-type active regions, a plurality of first gate lines extending lengthwise in the second horizontal direction on the plurality of fin-type active regions, a plurality of second gate lines arranged apart from the plurality of first gate lines in the second horizontal direction by a dummy active fin between a first fin-type active region and a second fin-type active region, wherein the dummy active fin protrudes in the vertical direction from the substrate and extends lengthwise in the first horizontal direction, and a gate cut insulating pattern extending lengthwise in the first horizontal direction between the plurality of first gate lines and the plurality of second gate lines and overlapping the dummy active fin in the vertical direction, wherein the device isolation film includes a first local isolation portion between the first fin-type active region and the dummy active fin and a second local isolation portion between the second fin-type active region and the dummy active fin.

According to yet another aspect of the inventive concept, there is provided an integrated circuit device including a first fin-type active region and a second fin-type active region, which protrude in a vertical direction from a substrate and are adjacent to each other, a device isolation film covering both sidewalls of each of the first fin-type active region and the second fin-type active region, a first nanosheet stack, including at least one nanosheet, arranged over the first fin-type active region, a first gate line surrounding the first nanosheet stack, a second gate line surrounding the second nanosheet stack, a dummy active fin separating the first fin-type active region from the second fin-type active region and protruding in the vertical direction from the substrate, a gate cut insulating pattern separating the first gate line from the second gate line, wherein the gate cut insulating pattern is on the dummy active fin in the vertical direction and extends above the first gate line and the second gate line, a first gate dielectric film separating the at least one nanosheet of the first nanosheet stack from the first gate line and contacting a first sidewall that faces the first gate line from among sidewalls of the gate cut insulating pattern, and a second gate dielectric film arranged between the second nanosheet stack and the second gate line and contacting a second sidewall of the gate cut insulating pattern opposite the first sidewall, wherein the device isolation film includes a first local isolation portion between the first fin-type active region and the dummy active fin, and a second local isolation portion between the second fin-type active region and the dummy active fin.

### BRIEF DESCRIPTION OF THE DRAWINGS

Embodiments will be more clearly understood from the following detailed description taken in conjunction with the accompanying drawings in which:

FIG. 1 is a planar layout diagram of some components of an integrated circuit device, according to some embodiments;

FIG. 2A is a cross-sectional view of some components of the integrated circuit device, taken along a line Y1-Y1′ of FIG. 1, FIG. 2B is a cross-sectional view of some components of the integrated circuit device, taken along a line X1-X1′ of FIG. 1, FIG. 2C is a cross-sectional view of some components of the integrated circuit device, taken along a line X2-X2′ of FIG. 1, and FIG. 2D is a cross-sectional view of some components of the integrated circuit device, taken along a line X3-X3′ of FIG. 1;

FIG. 3 is a cross-sectional view illustrating an integrated circuit device according to some embodiments;

FIG. 4 is a cross-sectional view illustrating an integrated circuit device according to some embodiments;

FIG. 5 is a cross-sectional view illustrating an integrated circuit device according to some embodiments;

FIGS. 6 to 16C are cross-sectional views respectively illustrating a sequence of processes of a method of fabricating an integrated circuit device, according to some embodiments, and in particular, FIGS. 6 to 11, 12A, 13A, 14A, 15A, and 16A are cross-sectional views each illustrating some components in a region corresponding to a cross-section taken along the line Y1-Y1′ of FIG. 1 according to the sequence of processes, FIGS. 12B, 13B, 14B, 15B, and 16B are cross-sectional views each illustrating some components in a region corresponding to a cross-section taken along the line X1-X1′ of FIG. 1 according to the sequence of processes, FIGS. 12C, 13C, 14C, 15C, and 16C are cross-sectional views each illustrating some components in a region corresponding to a cross-section taken along the line X2-X2′ of FIG. 1, and FIGS. 13D, 14D, and 15D are cross-sectional views each illustrating some components in a region corresponding to a cross-section taken along the line X3-X3′ of FIG. 1 according to the sequence of processes;

FIG. 17 is a cross-sectional view illustrating a method of fabricating an integrated circuit device, according to some embodiments; and

FIG. 18 is a cross-sectional view illustrating a method of fabricating an integrated circuit device, according to some embodiments.

### DETAILED DESCRIPTION OF THE EMBODIMENTS

Hereinafter, embodiments of the inventive concept will be described in detail with reference to the accompanying drawings. Like components are denoted by like reference numerals throughout the specification, and repeated descriptions thereof are omitted.

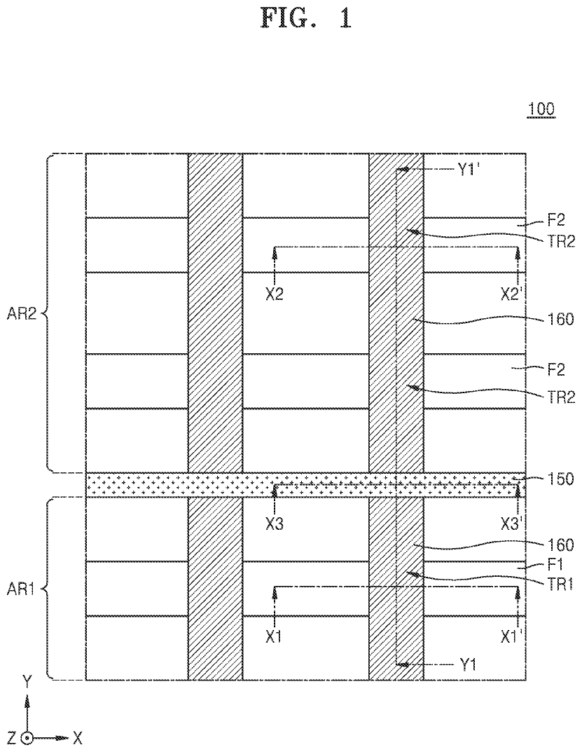

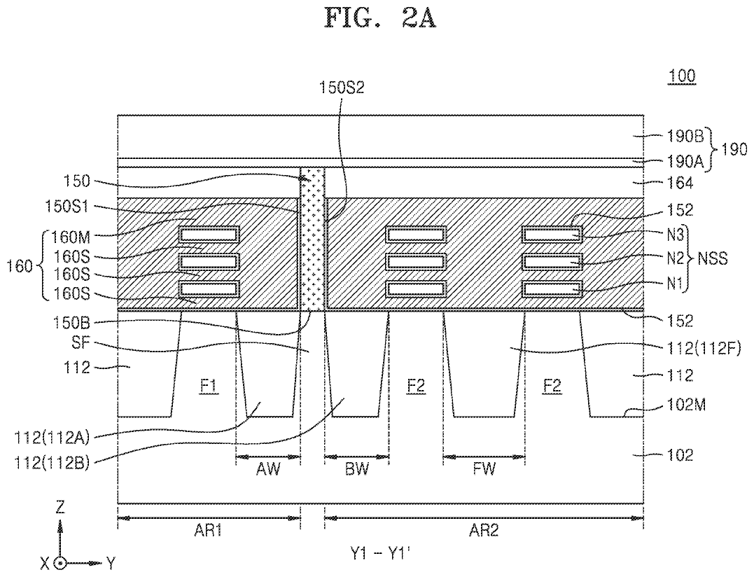

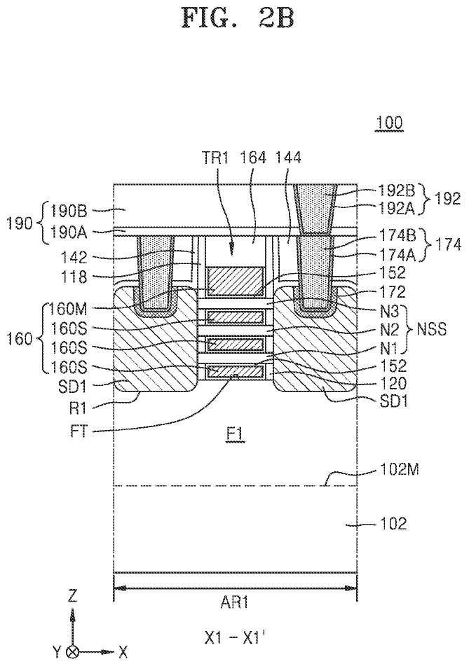

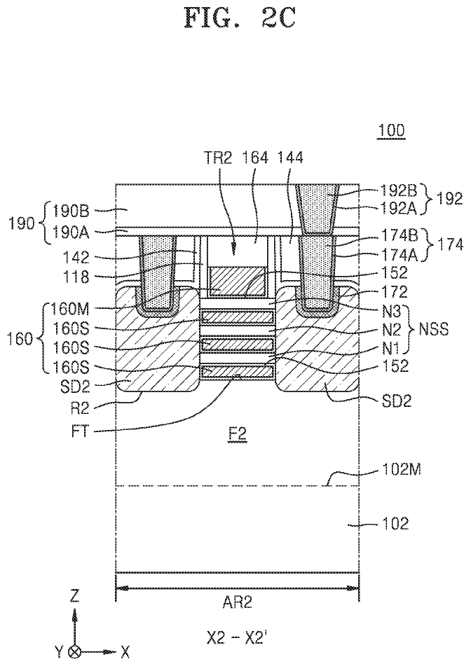

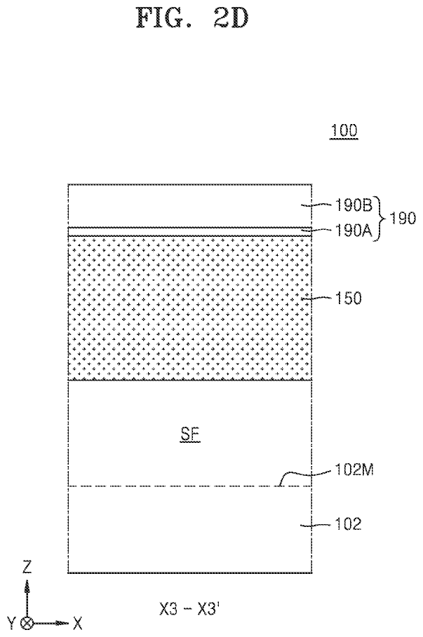

FIG. 1 is a planar layout diagram of some components of an integrated circuit device 100, according to some embodiments. FIG. 2A is a cross-sectional view of some components of the integrated circuit device 100, taken along a line Y1-Y1′ of FIG. 1, FIG. 2B is a cross-sectional view of some components of the integrated circuit device 100, taken along a line X1-X1′ of FIG. 1, FIG. 2C is a cross-sectional view of some components of the integrated circuit device 100, taken along a line X2-X2′ of FIG. 1, and FIG. 2D is a cross-sectional view of some components of the integrated circuit device 100, taken along a line X3-X3′ of FIG. 1. The integrated circuit device 100 including a field-effect transistor having a gate-all-around structure, which includes an active region having a nanowire or nanosheet shape and a gate surrounding the active region, is described with reference to FIGS. 1 and 2A to 2D.

Referring to FIGS. 1 and 2A to 2D, the integrated circuit device 100 may include a substrate 102, which includes a first device area AR1 and a second device area AR2, and a plurality of fin-type active regions F1 and F2, which protrude in a vertical direction (Z direction) from the first device area AR1 and the second device area AR2 of the substrate 102, respectively. The plurality of fin-type active regions F1 and F2 may extend parallel to each other in a first horizontal direction (X direction) and be spaced apart from each other in a second horizontal direction (Y direction) intersecting with the first horizontal direction (X direction). Herein, a fin-type active region F1 arranged in the first device area AR1 from among the plurality of fin-type active regions F1 and F2 may be referred to as a first fin-type active region, and a fin-type active region F2 arranged in the second device area AR2 from among the plurality of fin-type active regions F1 and F2 may be referred to as a second fin-type active region.

Although FIG. 1 illustrates one first fin-type active region F1 arranged in the first device area AR1 and two second fin-type active regions F2 arranged in the second device area AR2, this is only for convenience of illustration. Thus, two or more first fin-type active regions F1 may be arranged in the first device area AR1, and three or more second fin-type active regions F2 may be arranged in the second device area AR2.

The substrate 102 may include a semiconductor, such as Si or Ge, or a compound semiconductor, such as SiGe, SiC, GaAs, InAs, InGaAs, or InP. As used herein, each of the terms “SiGe”, “SiC”, “GaAs”, “InAs”, “InGaAs”, and “InP” refers to a material including elements contained in each term and is not a chemical formula representing a stoichiometric relationship. The substrate 102 may include a conductive region, for example, an impurity-doped well or an impurity-doped structure.

A device isolation film 112 may be arranged on the substrate 102 to cover both sidewalls of each of the plurality of fin-type active regions F1 and F2. The device isolation film 112 may include an oxide film, a nitride film, or a combination thereof, where the device isolation film 112 may be an electrically insulating material to electrically separate devices or conductive regions, for example, silicon oxide (SiO), silicon nitride (SiN), hafnium oxide (HfO), or a combination thereof.

A plurality of gate lines 160 may extend lengthwise, on the plurality of fin-type active regions F1 and F2, in the second horizontal direction (Y direction) intersecting with the first horizontal direction (X direction). In intersection areas between the plurality of fin-type active regions F1 and F2 and the plurality of gate lines 160, a plurality of nanosheet stacks NSS may be arranged over a fin top surface FT of each of the plurality of fin-type active regions F1 and F2. The plurality of nanosheet stacks NSS may be arranged apart from the plurality of fin-type active regions F1 and F2 in the vertical direction (Z direction) to face the fin top surface FT of each of the fin-type active regions F1 and F2. As used herein, the term “nanosheet” refers to a conductive structure having a cross-section that is substantially perpendicular to a current-flowing direction. The nanosheet should be understood as including a nanowire, where the width can be greater than the height of the nanosheet or the width and height can be approximately the same dimensions.

Each of the plurality of nanosheet stacks NSS may include a first nanosheet N1, a second nanosheet N2, and a third nanosheet N3, which overlap each other in the vertical direction (Z direction), over the fin top surface FT of each of the fin-type active regions F1 and F2. The first nanosheet N1, the second nanosheet N2, and the third nanosheet N3 may respectively have different vertical distances (Z-direction distances) from the fin top surface FT of each of the fin-type active regions F1 and F2. The respective numbers of nanosheet stacks NSS and gate lines 160 arranged on the fin top surface FT of each of the fin-type active regions F1 and F2 are not particularly limited. For example, one nanosheet stack NSS or the plurality of nanosheet stacks NSS and one gate line 160 or the plurality of gate lines 160 may be arranged on one fin-type active region F1 or F2.

FIGS. 2A to 2C each illustrate an example in which each of the plurality of nanosheet stacks NSS includes three nanosheets, that is, the first nanosheet N1, the second nanosheet N2, and the third nanosheet N3, but the inventive concept is not limited thereto. The number of nanosheets constituting one nanosheet stack NSS is not particularly limited. For example, each of the plurality of nanosheet stacks NSS may include one nanosheet, two nanosheets, or four or more nanosheets. Each of the first nanosheet N1, the second nanosheet N2, and the third nanosheet N3 may have a channel region. In some embodiments, the first nanosheet N1, the second nanosheet N2, and the third nanosheet N3 may have substantially the same thickness in the vertical direction (Z direction). In some embodiments, at least some of the first nanosheet N1, the second nanosheet N2, and the third nanosheet N3 may have different thicknesses from each other in the vertical direction (Z direction).

As shown in FIGS. 2A to 2C, the first nanosheet N1, the second nanosheet N2, and the third nanosheet N3, which are included in one nanosheet stack NSS, may have equal or similar sizes to each other in the first horizontal direction (X direction). In some embodiments, at least some of the first nanosheet N1, the second nanosheet N2, and the third nanosheet N3, which are included in one nanosheet stack NSS, may have different sizes from each other in the first horizontal direction (X direction). For example, in the first horizontal direction (X direction), the length of each of the first nanosheet N1 and the second nanosheet N2, which are relatively close to the fin top surface FT of each of the plurality of fin-type active regions F1 and F2, may be greater than the length of the third nanosheet N3, which is farthest from the fin top surface FT of each of the plurality of fin-type active regions F1 and F2.

A plurality of first recesses R1 may be formed in an upper surface of the first fin-type active region F1 in the first device area AR1, and a plurality of second recesses R2 may be formed in an upper surface of the second fin-type active region F2 in the second device area AR2. To form the plurality of first recesses R1, the first fin-type active region F1 may be etched by dry etching, wet etching, or a combination thereof, and to form the plurality of second recesses R2, the second fin-type active region F2 may be etched by dry etching, wet etching, or a combination thereof. FIGS. 2B and 2C each illustrate an example in which a level of a lowermost surface of each of the plurality of first recesses R1 and the plurality of second recesses R2 is lower than a level of the fin top surface FT of each of the plurality of fin-type active regions F1 and F2, but the inventive concept is not limited thereto. The level of the lowermost surface of each of the plurality of first recesses R1 and the plurality of second recesses R2 may be equal to or similar to the level of the fin top surface FT of each of the plurality of fin-type active regions F1 and F2, where a lowermost surface of a first or second recess R1, R2 may be coplanar with an adjacent fin top surface FT.

A plurality of first source/drain regions SD1 may be respectively formed in the plurality of first recesses R1 in the first device area AR1, and a plurality of second source/drain regions SD2 may be respectively formed in the plurality of second recesses R2 in the second device area AR2. The first source/drain regions SD1 may be formed on the surface of the first recesses R1 exposed by etching the first fin-type active region F1, and the second source/drain regions SD2 may be formed on the surface of the second recesses R2 exposed by etching the second fin-type active region F2. A semiconductor material may be epitaxially grown on a surface of the first fin-type active region F1 or second fin-type active region F2 exposed at bottom surfaces of the plurality of first or second recesses R1 and R2 and on a sidewall of each of the nanosheets.

In the first device area AR1 and the second device area AR2, the plurality of gate lines 160 may extend lengthwise in the second horizontal direction (Y direction) on the plurality of fin-type active regions F1 and F2 and the device isolation film 112. The plurality of gate lines 160 may be arranged on the plurality of fin-type active regions F1 and F2 to cover the plurality of nanosheet stacks NSS and to surround each of the first nanosheet N1, the second nanosheet N2, and the third nanosheet N3, which are included in each of the plurality of nanosheet stacks NSS. In the intersection areas between the plurality of fin-type active regions F1 and F2 and the plurality of gate lines 160, a plurality of transistors TR1 and TR2 may be formed on the substrate 102. In various embodiments, the first device area AR1 may be an NMOS transistor area, and the second device area AR2 may be a PMOS transistor area. A plurality of NMOS transistors TR1 may be respectively formed in intersection areas between the first fin-type active region F1 and the plurality of gate lines 160 in the first device area AR1, and a plurality of PMOS transistors TR2 may be respectively formed in intersection areas between the second fin-type active region F2 and the plurality of gate lines 160 in the second device area AR2.

Each of the plurality of gate lines 160 may include a main gate portion 160M and a plurality of sub-gate portions 160S. The main gate portion 160M may extend lengthwise in the second horizontal direction (Y direction) to cover an upper surface of the nanosheet stack NSS, where the main gate portion 160M can be above the uppermost nanosheet of the nanosheet stack NSS, for example, the third nanosheet N3. The plurality of sub-gate portions 160S may be integrally connected to the main gate portion 160M and may be respectively arranged one by one between the first nanosheet N1, the second nanosheet N2, and the third nanosheet N3 and between the first nanosheet N1 and each of the fin-type active regions F1 and F2, where the sub-gate portions 160S can be interposed between adjacent pairs of nanosheets in the nanosheet stack NSS.

Each of the plurality of gate lines 160 may include a metal, a metal nitride, a metal carbide, or a combination thereof. The metal may be selected from Ti, W, Ru, Nb, Mo, Hf, Ni, Co, Pt, Yb, Tb, Dy, Er, and Pd. The metal nitride may be selected from TiN and TaN. The metal carbide may include TiAlC. In some embodiments, each of the plurality of gate lines 160 may have a structure in which a metal nitride film, a metal film, a conductive capping film, and a gap-fill metal film are stacked in the stated order. The metal nitride film and the metal film may each include at least one metal selected from Ti, Ta, W, Ru, Nb, Mo, and Hf. The gap-fill metal film may include W, Al, or a combination thereof. Each of the plurality of gate lines 160 may include at least one work function metal-containing film. The at least one work function metal-containing film may include at least one metal selected from Ti, W. Ru, Nb, Mo, Hf, Ni, Co, Pt, Yb, Tb, Dy, Er, and Pd. In some embodiments, each of the plurality of gate lines 160 may include a stack structure including at least two layers that are selected from a first work function metal-containing film, a second work function metal-containing film, and a gap-fill metal film. For example, the first work function metal-containing film may include a TiN film. The second work function metal-containing film may include a combination of a first TiN film, a TiAlC film, and a second TiN film. In some embodiments, each of the plurality of gate lines 160 may include a TiN film, a stack structure of TiAlC/TiN/W, a stack structure of TiN/TaN/TiAlC/TiN/W, or a stack structure of TiN/TaN/TiN/TiAlC/TiN/W. However, a constituent material of each of the plurality of gate lines 160 is not limited to the examples set forth above and may undergo various changes and modifications without departing from the scope of the inventive concept.

In various embodiments, the plurality of gate lines 160 may have the same stack structure in the first device area AR1 and the second device area AR2. In various embodiments, the plurality of gate lines 160 may have different stack structures from each other in the first device area AR1 and the second device area AR2. Herein, a gate line 160 arranged in the first device area AR1 from among the plurality of gate lines 160 may be referred to as a first gate line, and a gate line 160 arranged in the second device area AR2 from among the plurality of gate lines 160 may be referred to as a second gate line.

As shown in FIGS. 1 and 2A, the plurality of gate lines 160 may include a pair of gate lines 160 arranged in a straight line in the second horizontal direction (Y direction) to be apart from each other in the second horizontal direction (Y direction). A gate line 160 located in the first device area AR1, out of the pair of colinear gate lines 160, may be arranged on the first fin-type active region F1 and extend lengthwise in the second horizontal direction (Y direction). A gate line 160 located in the second device area AR2, out of the pair of colinear gate lines 160, may be arranged on the second fin-type active region F2 and extend lengthwise in the second horizontal direction (Y direction). The gate line 160 in the second device area AR2 may be arranged apart from the gate line 160 in the first device area AR1 in the second horizontal direction (Y direction) to extend lengthwise along an extension line of the first gate line 160 in the first device area AR1 in the second horizontal direction (Y direction), where the gate line 160 in the second device area AR2 may be separated from the gate line 160 in the first device area AR1 by a gate cut insulating pattern 150.

As shown in FIGS. 1, 2A, and 2D, a gate cut insulating pattern 150 may be arranged between the gate line 160 in the first device area AR1 and the gate line 160 in the second device area AR2. The gate cut insulating pattern 150 may be arranged in a boundary region between the first device area AR1 and the second device area AR2.

A vertical level of an upper surface of the gate cut insulating pattern 150 may be located farther from the substrate 102 than a vertical level of an upper surface of each of the plurality of nanosheet stacks NSS. The vertical level of the upper surface of the gate cut insulating pattern 150 may be located farther from the substrate 102 than a vertical level of an upper surface of each of the plurality of gate lines 160. As used herein, the term “vertical level” refers to a distance in the vertical direction (Z direction or −Z direction) from a main surface 102M of the substrate 102, where the main surface 102M of the substrate 102 can be at the base of the first fin-type active region F1 and second fin-type active region F2.

A lower surface 150B of the gate cut insulating pattern 150 may be on an extension line of the fin top surface FT of each of the first fin-type active region F1 and the second fin-type active region F2 in the second horizontal direction (Y direction), where the lower surface 150B of the gate cut insulating pattern 150 may be coplanar with the fin top surface FT. A vertical level of the lower surface 150B of the gate cut insulating pattern 150 may be equal to or similar to a vertical level of the fin top surface FT of each of the first fin-type active region F1 and the second fin-type active region F2. The vertical level of the lower surface 150B of the gate cut insulating pattern 150 may be closer to the substrate 102 than a vertical level of a lower surface of each of the plurality of gate lines 160. In the vertical direction (Z direction), the height of the gate cut insulating pattern 150 may be greater than the height of each of the plurality of gate lines 160, such that the top surface of the gate cut insulating pattern 150 is above the top surface of the adjacent main gate portion 160M.

As shown in FIG. 2A, the gate cut insulating pattern 150 may have a first sidewall 150S1, which faces the gate line 160 in the first device area AR1, and a second sidewall 150S2, which faces the gate line 160 in the second device area AR2. At least one of the first sidewall 150S1 and the second sidewall 150S2 may include a portion extending in a direction perpendicular to the main surface 102M of the substrate 102, with an increasing distance from the substrate 102. A first sidewall 150S1 and a second sidewall 150S2 of the gate cut insulating pattern 150 can include a portion extending in an inclined direction with respect to a direction perpendicular to a main surface 102M of the substrate 102 with an increasing distance from the substrate, where both of the first sidewall 150S1 and the second sidewall 150S2 may extend in an inclined direction with respect to a direction perpendicular to a main surface 102M of the substrate 102. In some embodiments, the gate cut insulating pattern 150 may include, but is not limited to, silicon nitride (SiN), SiCN, SION, SiOCN, SiBN, SiBCN, SiOC, SiC, or a combination thereof.

The gate cut insulating pattern 150 may extend lengthwise in the first horizontal direction (X direction) to intersect with the plurality of gate lines 160. A pair of gate lines 160 adjacent to each other on opposite sides of the gate cut insulating pattern 150 in the second horizontal direction (Y direction) may be spaced apart from each other without being electrically connected to each other. A plurality of gate lines 160 arranged in a line in the second horizontal direction (Y direction), from among the plurality of gate lines 160, may be separated from each other by the gate cut insulating pattern 150. At least one gate line 160 from among the plurality of gate lines 160 may have a length determined by the gate cut insulating pattern 150, in the second horizontal direction (Y direction).

In various embodiments, a gate dielectric film 152 may be arranged between the gate line 160 and each of the first nanosheet N1, the second nanosheet N2, and the third nanosheet N3 constituting each of the plurality of nanosheet stacks NSS. The gate dielectric film 152 may include portions covering a surface of each of the first nanosheet N1, the second nanosheet N2, and the third nanosheet N3, portions covering sidewalls of the main gate portion 160M, and portions covering sidewalls of the gate cut insulating pattern 150. Herein, among gate dielectric films 152, a gate dielectric film 152 in the first device area AR1 may be referred to as a first gate dielectric film, and a gate dielectric film 152 in the second device area AR2 may be referred to as a second gate dielectric film. The gate dielectric film 152 may physically separate and electrically insulate the gate line 160 from the top surfaces of each of the plurality of fin-type active regions F1 and F2 and the top surfaces of device isolation film 112.

In some embodiments, the gate dielectric film 152 may include a stack structure of an interface film and a high-K film. The interface film may include a low-K material film having a dielectric constant of about 9 or less, for example, a silicon oxide film, a silicon oxynitride film, or a combination thereof. In some embodiments, the interface film may be omitted. The high-K film may include a material having a dielectric constant that is greater than that of a silicon oxide film. For example, the high-K film may have a dielectric constant of about 10 to about 25. The high-K film may include, but is not limited to, hafnium oxide (HfO). In various embodiments, the gate dielectric film 152 in the first device area AR1 and the gate dielectric film 152 in the second device area AR2 may have the same structure. In various embodiments, the gate dielectric film 152 in the first device area AR1 and the gate dielectric film 152 in the second device area AR2 may have different structures from each other.

The gate dielectric film 152 in the first device area AR1 may include a portion between the gate line 160 and each of the first nanosheet N1, the second nanosheet N2, and the third nanosheet N3 constituting the nanosheet stack NSS in the first device area AR1, and a portion contacting the first sidewall 150S1, which faces the gate line 160 in the first device area AR1, out of the sidewalls of the gate cut insulating pattern 150. The gate dielectric film 152 in the first device area AR1 may include a portion between the gate line 160 and the underlying first fin-type active regions F1. The gate dielectric film 152 can be on a portion of the first sidewall 150S1 extending in an inclined direction with respect to a direction perpendicular to a main surface 102M of the substrate 102 with an increasing distance from the substrate.

The gate dielectric film 152 in the second device area AR2 may include a portion between the gate line 160 and each of the first nanosheet N1, the second nanosheet N2, and the third nanosheet N3 constituting the nanosheet stack NSS in the second device area AR2, and a portion contacting the second sidewall 150S2, which faces the gate line 160 in the second device area AR2, out of the sidewalls of the gate cut insulating pattern 150. The gate dielectric film 152 in the second device area AR2 may include a portion between the gate line 160 and the underlying second fin-type active regions F2. The gate dielectric film 152 can be on a portion of the second sidewall 150S2 extending in an inclined direction with respect to a direction perpendicular to a main surface 102M of the substrate 102 with an increasing distance from the substrate.

In each of the first device area AR1 and the second device area AR2, the first nanosheet N1, the second nanosheet N2, and the third nanosheet N3 may respectively include semiconductor layers including the same element. In some embodiments, each of the first nanosheet N1, the second nanosheet N2, and the third nanosheet N3 may include an Si layer. In various embodiments, in the first device area AR1, the first nanosheet N1, the second nanosheet N2, and the third nanosheet N3 may be doped with a dopant of the same conductivity type as the conductivity type of the first source/drain region SD1. In the second device area AR2, the first nanosheet N1, the second nanosheet N2, and the third nanosheet N3 may be doped with a dopant of the same conductivity type as the conductivity type of the second source/drain region SD2. In some embodiments, the first nanosheet N1, the second nanosheet N2, and the third nanosheet N3 in the first device area AR1 may include an Si layer doped with an n-type dopant, and the first nanosheet N1, the second nanosheet N2, and the third nanosheet N3 in the second device area AR2 may include an Si layer doped with a p-type dopant. In some embodiments, the conductivity type of the first source/drain region SD1 may be the same as the conductivity type of the second source/drain region SD2, and the first nanosheet N1, the second nanosheet N2, and the third nanosheet N3 in the first device area AR1 and the second device area AR2 may respectively include Si layers doped with dopants of the same conductivity type.

As shown in FIG. 2A, the device isolation film 112 may include a first local isolation portion 112A and a second local isolation portion 112B, which are arranged between the first fin-type active region F1 and the second fin-type active region F2 adjacent to each other, and which are apart from each other in the second horizontal direction (Y direction) with the gate cut insulating pattern 150 therebetween. In addition, the device isolation film 112 may include an inter-active-region device isolation film 112F, which covers a sidewall farther from the first local isolation portion 112A and the second local isolation portion 112B out of sidewalls of each of the first fin-type active region F1 and the second fin-type active region F2. The inter-active-region device isolation film 112F can separate an adjacent pair of second fin-type active regions F2 in the second device area AR2. The first local isolation portion 112A can be between a first fin-type active region F1 and a dummy active fin SF and overlying gate cut insulating pattern 150, and the second local isolation portion 112B can be between a second fin-type active region F2 and the dummy active fin SF and gate cut insulating pattern 150. The dummy active fin SF can physically separate the first device area AR1 from the second device area AR2.

In the second horizontal direction (Y direction), a width AW of the first local isolation portion 112A may be equal to or different from a width BW of the second local isolation portion 112B. In the second horizontal direction (Y direction), each of the width AW of the first local isolation portion 112A and the width BW of the second local isolation portion 112B may be less than a width FW of the inter-active-region device isolation film 112F. However, the inventive concept is not limited thereto. For example, in the second horizontal direction (Y direction), the width of at least one of the first local isolation portion 112A and the second local isolation portion 112B may be equal to or greater than the width FW of the inter-active-region device isolation film 112F. The width AW of the first local isolation portion 112A can determine the separation distance between the first fin-type active region F1 and the dummy active fin SF. The width BW of the second local isolation portion 112B can determine the separation distance between the second fin-type active region F2 and the dummy active fin SF, where the second fin-type active region F2 can be separated from the dummy active fin SF by a greater or lesser distance than the first fin-type active region F1.

As shown in FIGS. 2A and 2D, a dummy active fin SF may be arranged between the first local isolation portion 112A and the second local isolation portion 112B and protrude in the vertical direction (Z direction) from the main surface 102M of the substrate 102 toward the gate cut insulating pattern 150. The gate cut insulating pattern 150 can overlie and be vertically aligned with the dummy active fin SF. The plurality of fin-type active regions F1 and F2 in the first device area AR1 and the second device area AR2 and the dummy active fin SF between the first device area AR1 and the second device area AR2 may each be integrally connected to the substrate 102. The dummy active fin SF may be arranged between the first fin-type active region F1 in the first device area AR1 and the second fin-type active region F2 in the second device area AR2 and extend parallel to the first fin-type active region F1 and the second fin-type active region F2.

The dummy active fin SF may be arranged to overlap the gate cut insulating pattern 150 in the vertical direction (Z direction). The dummy active fin SF may include the same material as at least one of the first fin-type active region F1 and the second fin-type active region F2.

As shown in FIG. 1, the gate cut insulating pattern 150 and underlying dummy active fin SF may extend lengthwise in the first horizontal direction (X direction) between the adjacent pair of the first fin-type active region F1 and the second fin-type active region F2. The gate cut insulating pattern 150 may be arranged on the dummy active fin SF and may extend lengthwise in the first horizontal direction (X direction) between a plurality of gate lines 160 in the first device area AR1 and a plurality of gate lines 160 in the second device area AR2 from among the plurality of gate lines 160. The lower surface 150B of the gate cut insulating pattern 150 may contact an upper surface of the dummy active fin SF.

As shown in FIG. 2A, the first local isolation portion 112A of the device isolation film 112 may be arranged between the first fin-type active region F1 and the dummy active fin SF, and the second local isolation portion 112B of the device isolation film 112 may be arranged between the second fin-type active region F2 and the dummy active fin SF.

Both sidewalls of each of the plurality of gate lines 160 on the plurality of fin-type active regions F1 and F2 and the device isolation film 112 may be covered by a plurality of outer insulating spacers 118. Each of the plurality of outer insulating spacers 118 may be arranged on the upper surface of the nanosheet stack NSS to cover both sidewalls of the main gate portion 160M (see e.g., FIG. 2B). At least a portion of each of the plurality of outer insulating spacers 118 may be separated from the gate line 160 by the gate dielectric film 152 positioned therebetween. The plurality of outer insulating spacers 118 may each include an electrically insulating, dielectric material, including, but not limited to, silicon nitride (SiN), silicon oxide (SiO), SiCN, SiBN, SION, SiOCN, SiBCN, SiOC, or a combination thereof. As used herein, each of the terms “SiCN”, “SiBN”, “SION”, “SiOCN”, “SiBCN”, and “SiOC” refers to a material including elements contained in each term and is not a chemical formula representing a stoichiometric relationship.

As shown in FIGS. 2B and 2C, in the first device area AR1 and the second device area AR2, both sidewalls of each of the plurality of sub-gate portions 160s, located between adjacent pairs of the first nanosheet N1, the second nanosheet N2, and the third nanosheet N3 and between the first nanosheet N1 and the second fin-type active region F2, may be separated from the first and second source/drain regions SD1 and SD2 with the gate dielectric film 152 therebetween. A plurality of first and second source/drain regions SD1 and SD2 may each face the nanosheet stack NSS and the plurality of sub-gate portions 160S in the first horizontal direction (X direction), where a first source/drain region SD1 can be on each of opposite sides and in electrical contact with the nanosheets of the intervening nanosheet stack NSS in the first device area AR1, and a second source/drain region SD2 can be on each of opposite sides and in electrical contact with the nanosheets of the intervening nanosheet stack NSS in the second device area AR2.

As shown in FIG. 2B, in areas between the first nanosheet N1, the second nanosheet N2, and the third nanosheet N3 and between the first nanosheet N1 and the first fin-type active region F1 in the first device area AR1, a plurality of inner insulating spacers 120 may be arranged between the first source/drain regions SD1 and the plurality of sub-gate portions 160S. Both sidewalls of each of the plurality of sub-gate portions 160S in the first device area AR1 may be separated from an inner insulating spacer 120 by the gate dielectric film 152 positioned therebetween. Each of the plurality of sub-gate portions 160S in the first device area AR1 may be separated from the first source/drain region SD1 by the gate dielectric film 152 and the inner insulating spacer 120 positioned therebetween. Each of the plurality of inner insulating spacers 120 may contact the first source/drain region SD1. At least a portion of each of the plurality of inner insulating spacers 120 may overlap an outer insulating spacer 118 in the vertical direction (Z direction). The inner insulating spacer 120 may include an electrically insulating, dielectric material, including, but not limited to, silicon nitride (SiN), silicon oxide (SiO), SiCN, SiBN, SION, SIOCN, SiBCN, SiOC, or a combination thereof. The inner insulating spacer 120 may further include an air gap. In various embodiments, the inner insulating spacer 120 may include the same material as the outer insulating spacer 118. In various embodiments, the inner insulating spacer 120 and the outer insulating spacer 118 may include different materials from each other.

In the first device area AR1, each of the plurality of first source/drain regions SD1 may face the plurality of sub-gate portions 160S with the inner insulating spacer 120 therebetween, in the first horizontal direction (X direction). Each of the plurality of first source/drain regions SD1 may not contact the gate dielectric film 152. In some embodiments, the plurality of inner insulating spacers 120 in the first device area AR1 may be omitted. In this case, the plurality of first source/drain regions SD1 may respectively include portions contacting the gate dielectric film 152.

As shown in FIG. 2C, in the second device area AR2, both sidewalls of each of the plurality of sub-gate portions 160S, between the first nanosheet N1, the second nanosheet N2, and the third nanosheet N3 and between the first nanosheet N1 and the second fin-type active area F2, may be separated from the second source/drain regions SD2 by the gate dielectric film 152 positioned therebetween. The gate dielectric film 152 may include a portion contacting the second source/drain region SD2. Each of the plurality of source/drain regions SD2 may face the nanosheet stack NSS and the plurality of sub-gate portions 160S in the first horizontal direction (X direction).

As shown in FIGS. 2A to 2C, the gate line 160 and the gate dielectric film 152 that covers a sidewall of the gate line 160 may be covered by a capping insulating pattern 164. The capping insulating pattern 164 may include a silicon nitride film. As shown in FIG. 2A, the upper surface of the gate cut insulating pattern 150 may be coplanar with an upper surface of the capping insulating pattern 164.

In the first device area AR1, the main gate portion 160M of the gate line 160 may be separated from the first source/drain regions SD1 by the outer insulating spacer 118 positioned therebetween. In the second device area AR2, the main gate portion 160M of the gate line 160 may be separated from the second source/drain region SD2 by the outer insulating spacer 118 positioned therebetween.

In various embodiments, the first device area AR1 may be an NMOS transistor area, and the second device area AR2 may be a PMOS transistor area. In this case, the plurality of first source/drain regions SD1 in the first device area AR1 may each include an Si layer doped with an n-type dopant or an SiC layer doped with an n-type dopant, and the plurality of second source/drain regions SD2 in the second device area AR2 may each include an SiGe layer doped with a p-type dopant. The n-type dopant may be selected from phosphorus (P), arsenic (As), and antimony (Sb). The p-type dopant may be selected from boron (B) and gallium (Ga).

The plurality of first source/drain regions SD1 in the first device area AR1 may be different in shapes and sizes from the plurality of second source/drain regions SD2 in the second device area AR2. However, the inventive concept is not limited thereto, and a plurality of first and second source/drain regions SD1 and SD2 having various shapes and sizes may be formed in the first device area AR1 and the second device area AR2, respectively.

As shown in FIGS. 2B and 2C, the plurality of first and second source/drain regions SD1 and SD2 may be covered by an insulating liner 142. The insulating liner 142 may conformally cover the outer insulating spacer 118 and a surface of each of the plurality of first and second source/drain regions SD1 and SD2. The insulating liner 142 may include an electrically insulating, dielectric material, including, but not limited to, SiN, SiCN, SiBN, SION, SiOCN, SiBCN, SiOC, SiO₂, or a combination thereof.

The insulating liner 142 in the first device area AR1 and the second device area AR2 may be covered by an inter-gate dielectric 144. The inter-gate dielectric 144 may include a silicon oxide film, a silicon nitride film, SiON, SiOCN, or a combination thereof.

The inter-gate dielectric 144, a plurality of capping insulating patterns 164, and the gate cut insulating pattern 150 may be covered by an insulating structure 190. The upper surface of the gate cut insulating pattern 150 may be in contact with a lower surface of the insulating structure 190. The insulating structure 190 may include an etch stop film 190A and an interlayer dielectric 190B. As shown in FIGS. 2A and 2D, the upper surface of the gate cut insulating pattern 150 may be in contact with a lower surface of the etch stop film 190A of the insulating structure 190. The etch stop film 190A may include silicon carbide (SiC), SiN, nitrogen-doped silicon carbide (SiC:N), SiOC, AlN, AlON, AlO, AlOC, or a combination thereof. The interlayer dielectric 190B may include an oxide film, a nitride film, an ultra-low K (ULK) film having an ultra-low dielectric constant (that is, K) of about 2.2 to about 2.4, or a combination thereof. For example, the interlayer dielectric 190B may include a tetraethylorthosilicate (TEOS) film, a high density plasma (HDP) film, a boro-phospho-silicate glass (BPSG) film, a flowable chemical vapor deposition (FCVD) oxide film, an SiON film, an SiN film, an SiOC film, an SiCOH film, or a combination thereof.

As shown in FIGS. 2B and 2C, a plurality of source/drain contacts 174 and a plurality of source/drain via contacts 192 may be formed on the plurality of first and second source/drain regions SD1 and SD2 in the first device area AR1 and the second device area AR2. Each of the plurality of first and second source/drain regions SD1 and SD2 may be connected to a conductive line thereover via the plurality of source/drain contacts 174 and the plurality of source/drain via contacts 192.

A metal silicide film 172 may be formed between a source/drain contact 174 and each of the first and second source/drain regions SD1 and SD2, where the metal silicide film 172 can be in physical and electrical contact with both the source/drain contact 174 and the first source/drain regions SD1 or second source/drain regions SD2. In some embodiments, the metal silicide film 172 may include Ti, W, Ru, Nb, Mo, Hf, Ni, Co. Pt, Yb, Tb, Dy, Er, or Pd. For example, the metal silicide film 172 may include titanium silicide (TiSi). Each of the plurality of source/drain contacts 174 may pass through the inter-gate dielectric 144 and the insulating liner 142 in the vertical direction (Z direction) to contact the metal silicide film 172. Each of the plurality of source/drain via contacts 192 may pass through the insulating structure 190 in the vertical direction (Z direction) to contact an upper surface of the source/drain contact 174.

Each of the plurality of source/drain contacts 174 may include a conductive barrier film 174A and a metal plug 174B. Each of the plurality of source/drain via contacts 192 may include a conductive barrier film 192A and a metal plug 192B. Each of the conductive barrier films 174A and 192A may include Ti, Ta, TiN, TaN, or a combination thereof, and each of the metal plugs 174B and 192B may include W, Co, Cu, Ru, Mn, or a combination thereof, but the inventive concept is not limited thereto. In some embodiments, a sidewall of each of the plurality of source/drain contacts 174 and the plurality of source/drain via contacts 192 may be surrounded by a contact insulating spacer physically and electrically separating the inter-gate dielectric 144 or insulating structure 190 from the conductive barrier films 174A or conductive barrier film 192A, respectively. The contact insulating spacer may include, but is not limited to, SiCN, SiCON, silicon nitride (SiN), or a combination thereof.

A gate contact may be formed on each of the plurality of gate lines 160. Each of the plurality of gate lines 160 may be connected to a conductive line thereover via the gate contact. The gate contact may have a similar structure to that described regarding the source/drain contact 174 and the source/drain via contact 192.

The integrated circuit device 100 described with reference to FIGS. 1 and 2A to 2D includes the gate cut insulating pattern 150 between the gate line 160 in the first device area AR1 and the gate line 160 in the second device area AR2. A space in which the gate cut insulating pattern 150 is located may be defined in a process of forming the fin-type active regions F1 and F2 on the substrate 102. Therefore, along with the increasing degree of integration and down-scaling of the integrated circuit device 100, even when components in reduced device areas (for example, the first device area AR1 and the second device area AR2) have relatively high aspect ratios, the width of the gate cut insulating pattern 150 may be easily reduced, and the possibility of the generation of process defects due to the gate cut insulating pattern 150 during a fabrication process of the integrated circuit device 100 may be removed. Therefore, there may be an effect in improving the performance and reliability of each of the plurality of transistors TR1 and TR2 formed in the first device area AR1 and the second device area AR2.

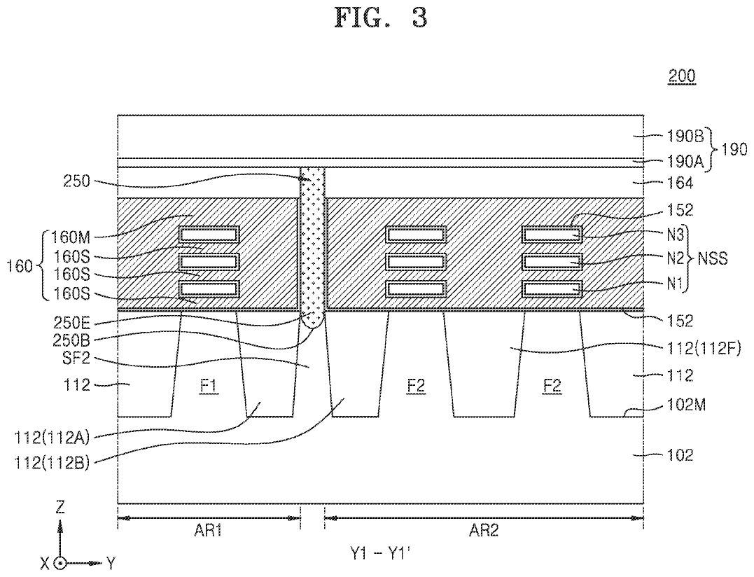

FIG. 3 is a cross-sectional view illustrating an integrated circuit device 200 according to some embodiments. FIG. 3 illustrates some components in a region corresponding to a cross-section taken along the line Y1-Y1′ of FIG. 1. In FIG. 3, the same reference numerals as in FIGS. 1 and 2A to 2D respectively denote the same members, and here, repeated descriptions thereof are omitted.

Referring to FIG. 3, the integrated circuit device 200 may have substantially the same configuration as the integrated circuit device 100 described with reference to FIGS. 1 and 2A to 2D. However, the integrated circuit device 200 includes a gate cut insulating pattern 250 between the gate line 160 in the first device area AR1 and the gate line 160 in the second device area AR2.

The gate cut insulating pattern 250 may have substantially the same configuration as the gate cut insulating pattern 150 described with reference to FIGS. 1 and 2A to 2D. However, the gate cut insulating pattern 250 may include a lower extension portion 250E between the first local isolation portion 112A and the second local isolation portion 112B. The lower extension portion 250E of the gate cut insulating pattern 250 may be arranged closer to the substrate 102 than a vertical level of an upper surface of each of the first local isolation portion 112A and the second local isolation portion 112B. The lower extension portion 250E of the gate cut insulating pattern 250 can extend below the gate line 160 and the underlying portion of the gate dielectric film 152, where the lower surface 250B of the gate cut insulating pattern 250 can have a curved surface extending into a dummy active fin SF2. Having the gate cut insulating pattern 250 extending below the gate dielectric film 152 and into a dummy active fin SF2 may reduce leakage current into the dummy active fin SF2. A vertical level of a lower surface 250B of the gate cut insulating pattern 250 may be closer to the substrate 102 than a vertical level of the fin top surface FT of at least one of the first fin-type active region F1 and the second fin-type active region F2. In some embodiments, the lower surface 250B of the gate cut insulating pattern 250 may have a convex shape toward the substrate 102.

A dummy active fin SF2 may be arranged between the first local isolation portion 112A and the second local isolation portion 112B to protrude from the main surface 102M of the substrate 102 toward the gate cut insulating pattern 250 in the vertical direction (Z direction). The plurality of fin-type active regions F1 and F2 in the first device area AR1 and the second device area AR2 and the dummy active fin SF2 between the first device area AR1 and the second device area AR2 may each be integrally connected to the substrate 102.

The dummy active fin SF2 may be arranged to overlap the gate cut insulating pattern 250 in the vertical direction (Z direction). An upper surface of the dummy active fin SF2 may be in contact with the lower surface 250B of the gate cut insulating pattern 250. The upper surface of the dummy active fin SF2 may have a concave shape toward the gate cut insulating pattern 250. More detailed configurations of the gate cut insulating pattern 250 and the dummy active fin SF2 are substantially the same as described regarding the gate cut insulating pattern 150 and the dummy active fin SF with reference to FIGS. 1.2A, and 2D.

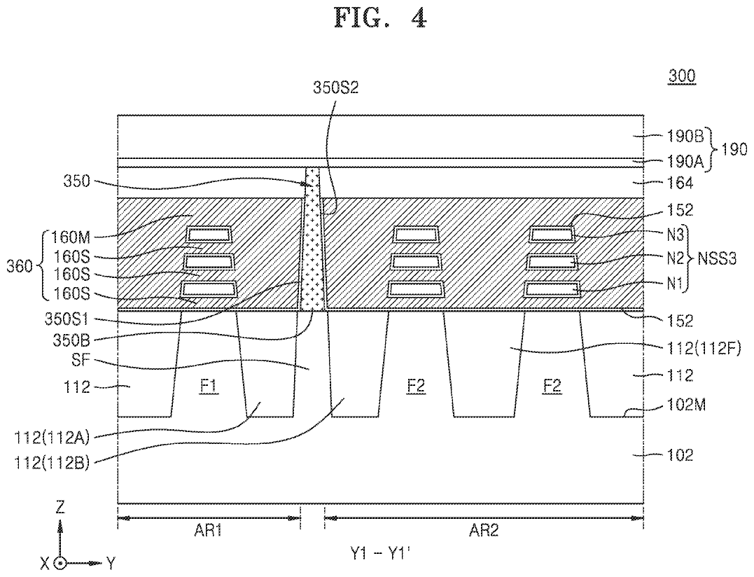

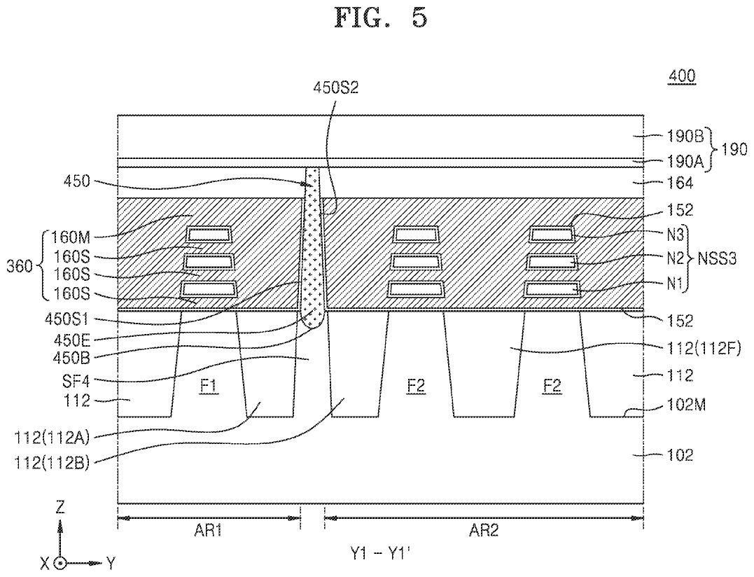

FIG. 4 is a cross-sectional view illustrating an integrated circuit device 300 according to some embodiments. FIG. 4 illustrates some components in a region corresponding to a cross-section taken along the line Y1-Y1′ of FIG. 1. In FIG. 4, the same reference numerals as in FIGS. 1 and 2A to 2D respectively denote the same members, and here, repeated descriptions thereof are omitted.

Referring to FIG. 4, the integrated circuit device 300 may have substantially the same configuration as the integrated circuit device 100 described with reference to FIGS. 1 and 2A to 2D. However, the integrated circuit device 300 includes a gate cut insulating pattern 350 between the gate line 160 in the first device area AR1 and the gate line 160 in the second device area AR2.

The gate cut insulating pattern 350 may have substantially the same configuration as the gate cut insulating pattern 150 described with reference to FIGS. 1 and 2A to 2D. However, the gate cut insulating pattern 350 may have a first sidewall 350S1, which faces the gate line 160 in the first device area AR1, and a second sidewall 350S2, which faces the gate line 160 in the second device area AR2. Each of the first sidewall 350S1 and the second sidewall 350S2 of the gate cut insulating pattern 350 may extend in an oblique direction with respect to a direction perpendicular to the main surface 102M of the substrate 102 with an increasing distance from the substrate 102, and the width of the gate cut insulating pattern 350 in the second horizontal direction (Y direction) may gradually decrease away from the substrate 102.

The dummy active fin SF may be arranged to overlap the gate cut insulating pattern 350 in the vertical direction (Z direction). The upper surface of the dummy active fin SF may be in contact with a lower surface 350B of the gate cut insulating pattern 350. The dummy active fin SF may have a width at a top surface greater than the width of the gate cut insulating pattern 350 at a bottom surface. A more detailed configuration of the gate cut insulating pattern 350 is substantially the same as described regarding the gate cut insulating pattern 150 with reference to FIGS. 1, 2A, and 2D.

The integrated circuit device 300 may include a plurality of nanosheet stacks NSS3 arranged over the fin top surface FT of each of the plurality of fin-type active regions F1 and F2. A detailed configuration of the plurality of nanosheet stacks NSS3 is substantially the same as described regarding the plurality of nanosheet stacks NSS with reference to FIGS. 2A to 2C. However, the width of each of the first nanosheet N1, the second nanosheet N2, and the third nanosheet N3 of the plurality of nanosheet stacks NSS3 in the second horizontal direction (Y direction) may gradually decrease away from the substrate 102, where the width in the second horizontal direction (Y direction) of an uppermost nanosheet in the nanosheet stack NSS3 can be less than the width in the second horizontal direction (Y direction) of a lowermost nanosheet in the nanosheet stack NSS3. The sidewalls of the nanosheets N1, N2, N3 in the nanosheet stack NSS3 can be oblique with respect to a direction perpendicular to the main surface 102M of the substrate 102.

FIG. 5 is a cross-sectional view illustrating an integrated circuit device 400 according to some embodiments. FIG. 5 illustrates some components in a region corresponding to a cross-section taken along the line Y1-Y1′ of FIG. 1. In FIG. 5, the same reference numerals as in FIGS. 1 and 2A to 2D respectively denote the same members, and here, repeated descriptions thereof are omitted.

Referring to FIG. 5, the integrated circuit device 400 may have substantially the same configuration as the integrated circuit device 300 described with reference to FIG. 4. However, the integrated circuit device 400 includes a gate cut insulating pattern 450 between the gate line 160 in the first device area AR1 and the gate line 160 in the second device area AR2.

The gate cut insulating pattern 450 may have substantially the same configuration as the gate cut insulating pattern 150 described with reference to FIGS. 1 and 2A to 2D. However, the gate cut insulating pattern 450 may include a lower extension portion 450E between the first local isolation portion 112A and the second local isolation portion 112B. The lower extension portion 450E of the gate cut insulating pattern 450 may be arranged closer to the substrate 102 than the vertical level of the upper surface of each of the first local isolation portion 112A and the second local isolation portion 112B. A vertical level of a lower surface 450B of the gate cut insulating pattern 450 may be closer to the substrate 102 than the vertical level of the fin top surface FT of at least one of the first fin-type active region F1 and the second fin-type active region F2. In some embodiments, the lower surface 450B of the gate cut insulating pattern 450 may have a convex shape toward the substrate 102.

A dummy active fin SF4 may be arranged between the first local isolation portion 112A and the second local isolation portion 112B to protrude from the main surface 102M of the substrate 102 toward the gate cut insulating pattern 450 in the vertical direction (Z direction). The plurality of fin-type active regions F1 and F2 in the first device area AR1 and the second device area AR2 and the dummy active fin SF4 between the first device area AR1 and the second device area AR2 may each be integrally connected to the substrate 102.

The dummy active fin SF4 may be arranged to overlap the gate cut insulating pattern 450 in the vertical direction (Z direction). An upper surface of the dummy active fin SF4 may be in contact with the lower surface 450B of the gate cut insulating pattern 450. The upper surface of the dummy active fin SF4 may have a concave shape toward the gate cut insulating pattern 450.

The gate cut insulating pattern 450 may have a first sidewall 450S1, which faces the gate line 160 in the first device area AR1, and a second sidewall 450S2, which faces the gate line 160 in the second device area AR2. Each of the first sidewall 450S1 and the second sidewall 450S2 of the gate cut insulating pattern 450 may extend in an oblique direction with respect to a direction perpendicular to the main surface 102M of the substrate 102 with an increasing distance from the substrate 102, and the width of the gate cut insulating pattern 450 in the second horizontal direction (Y direction) may gradually decrease away from the substrate 102.

More detailed configurations of the gate cut insulating pattern 450 and the dummy active fin SF4 are substantially the same as described regarding the gate cut insulating pattern 150 and the dummy active fin SF with reference to FIGS. 1.2A, and 2D.

The integrated circuit devices 100, 200, 300, and 400 described with reference to FIGS. 1 to 5 respectively include the gate cut insulating patterns 150, 250, 350, and 450 between the gate line 160 in the first device area AR1 and the second device area AR2. A space in which each of the gate cut insulating patterns 150, 250, 350, and 450 is located may be defined in a process of forming the fin-type active regions F1 and F2 on the substrate 102. Therefore, even when the degree of integration of each of the integrated circuit devices 100, 200, 300, and 400 increases and components in the first device area AR1 and the second device area AR2 have relatively high aspect ratios, the width of each of the gate cut insulating patterns 150, 250, 350, and 450 may be easily reduced, and the possibility of the generation of process defects due to each of the gate cut insulating patterns 150, 250, 350, and 450 during a fabrication process of each of the integrated circuit devices 100, 200, 300, and 400 may be removed. Therefore, there may be an effect in improving the performance and reliability of each of the plurality of transistors TR1 and TR2 formed in the first device area AR1 and the second device area AR2.

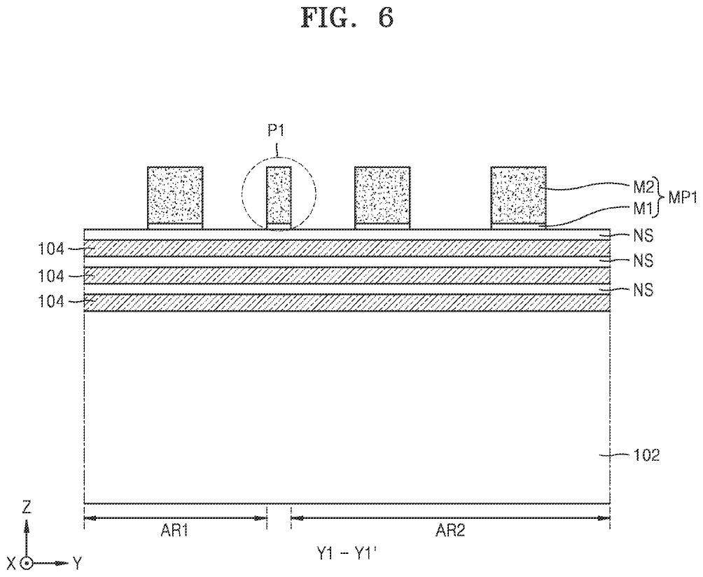

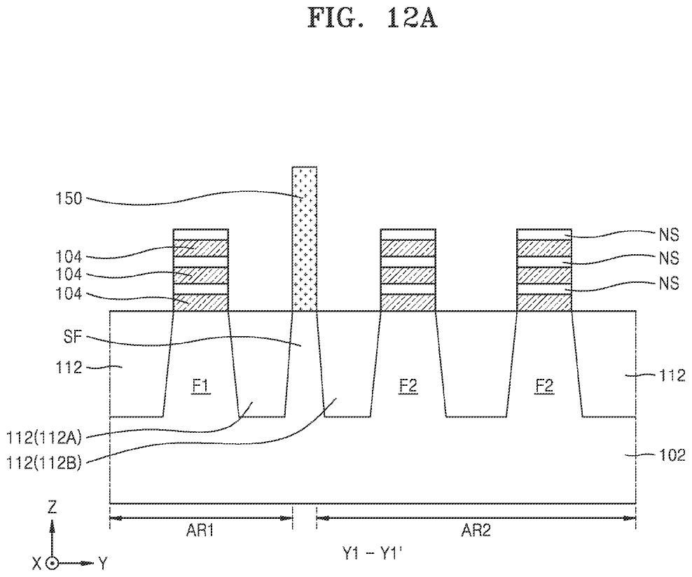

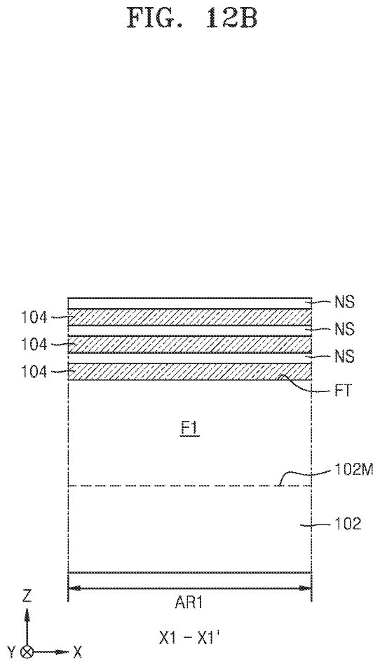

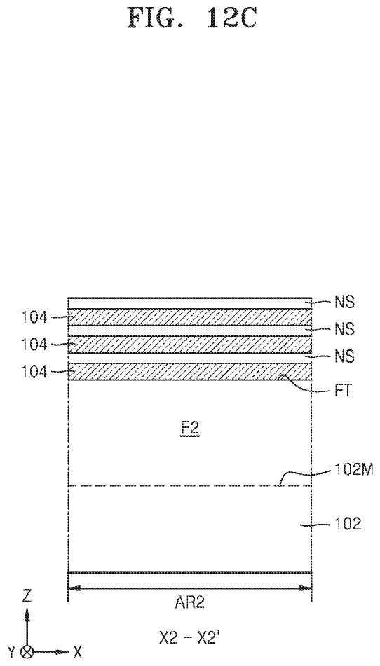

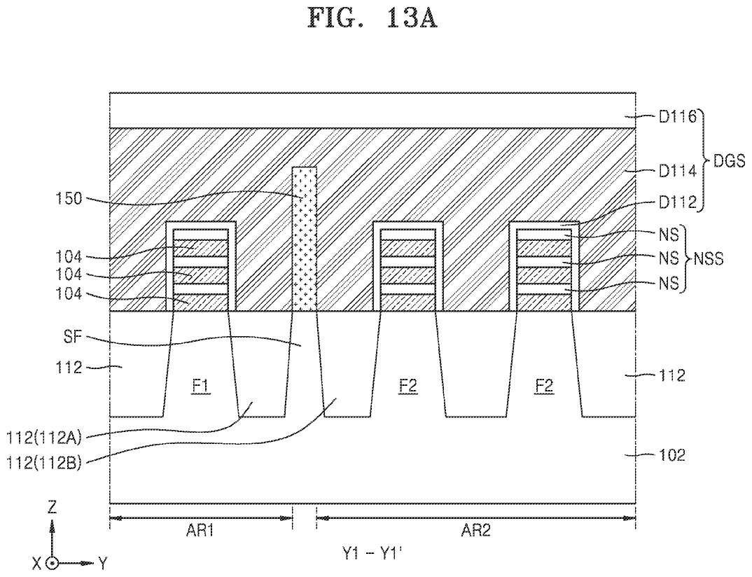

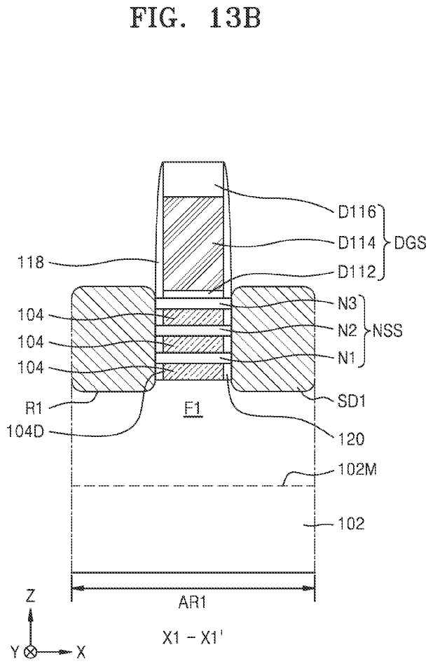

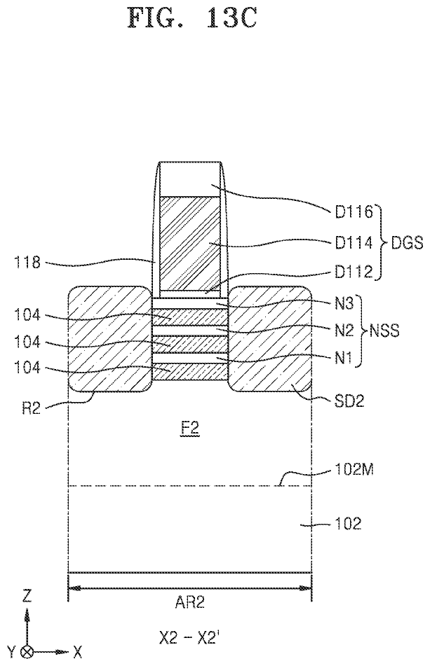

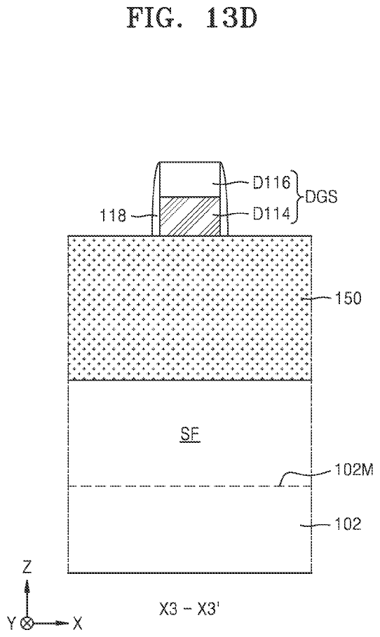

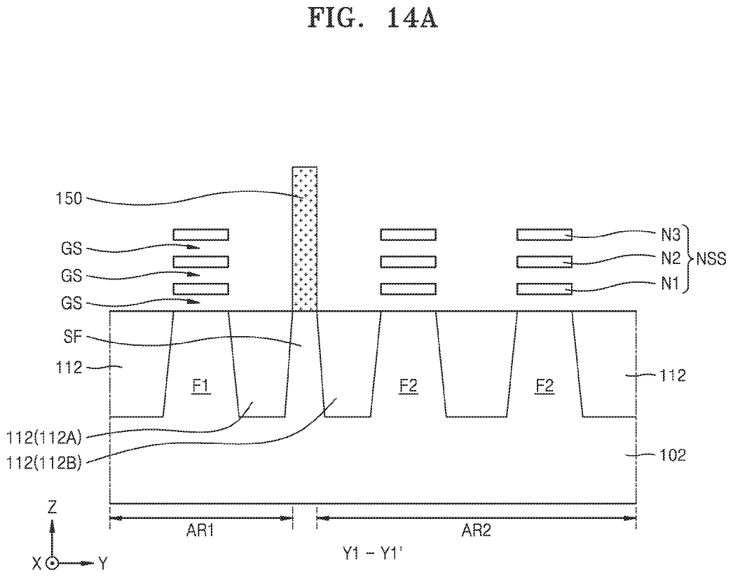

FIGS. 6 to 16C are cross-sectional views respectively illustrating a sequence of processes of a method of fabricating an integrated circuit device, according to some embodiments, and in particular, FIGS. 6 to 11, 12A, 13A, 14A, 15A, and 16A are cross-sectional views each illustrating some components in a region corresponding to a cross-section taken along the line Y1-Y1′ of FIG. 1 according to the sequence of processes, FIGS. 12B, 13B. 14B, 15B, and 16B are cross-sectional views each illustrating some components in a region corresponding to a cross-section taken along the line X1-X1′ of FIG. 1 according to the sequence of processes, FIGS. 12C, 13C, 14C, 15C, and 16C are cross-sectional views each illustrating some components in a region corresponding to a cross-section taken along the line X2-X2′ of FIG. 1, and FIGS. 13D, 14D, and 15D are cross-sectional views each illustrating some components in a region corresponding to a cross-section taken along the line X3-X3′ of FIG. 1 according to the sequence of processes. An example of a method of fabricating the integrated circuit device 100 shown in FIGS. 1 and 2A to 2D is described with reference to FIGS. 6 to 16C. In FIGS. 6 to 16C, the same reference numerals as in FIGS. 1 and 2A to 2D respectively denote the same members, and here, repeated descriptions thereof are omitted.

Referring to FIG. 6, a stack structure, in which a plurality of sacrificial semiconductor layers 104 and a plurality of nanosheet semiconductor layers NS are alternately stacked one by one, may be formed on the substrate 102, and then, a first mask pattern MP1 may be formed on the stack structure in the first device area AR1 and the second device area AR2.

The first mask pattern MP1 may include a gate cut mask portion (a portion indicated by a dashed line P1 in FIG. 6) arranged in an area corresponding to a planar position at which the gate cut insulating pattern 150 (see FIGS. 1, 2A, and 2D) is intended to be formed. In some embodiments, the first mask pattern MP1 may include a double-layer structure of a silicon oxide film M1 and a silicon nitride film M2.

Each of the plurality of sacrificial semiconductor layers 104 and each of the plurality of nanosheet semiconductor layers NS may respectively include semiconductor materials having different etch selectivities from each other. In some embodiments, each of the plurality of nanosheet semiconductor layers NS may include an Si layer, and each of the plurality of sacrificial semiconductor layers 104 may include an SiGe layer. In some embodiments, Ge may be present in a constant amount in the plurality of sacrificial semiconductor layers 104. The SiGe layer constituting each of the plurality of sacrificial semiconductor layers 104 may include Ge in a constant amount selected from a range of about 5 at % to about 60 at %, for example, about 10 at % to about 40 at %. The amount of Ge in the SiGe layer constituting each of the plurality of sacrificial semiconductor layers 104 may be variously selected, as needed.

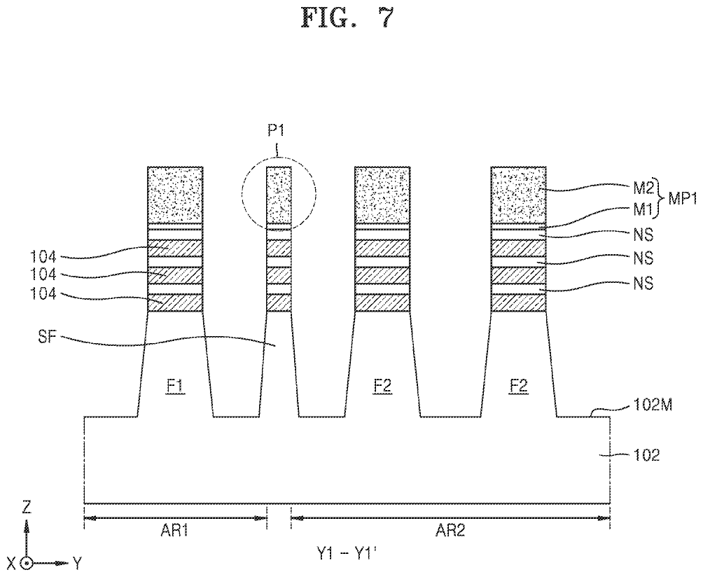

Referring to FIG. 7, the plurality of sacrificial semiconductor layers 104, the plurality of nanosheet semiconductor layers NS, and the substrate 102 may each be partially etched by using the first mask pattern MP1 as an etch mask, thereby forming the plurality of fin-type active regions F1 and F2, which protrude upward in the vertical direction (Z direction) from the substrate 102 and extend parallel to each other in the first horizontal direction (X direction), and the dummy active fin SF between the first device area AR1 and the second device area AR2. The stack structure, in which the plurality of sacrificial semiconductor layers 104 and the plurality of nanosheet semiconductor layers NS are alternately stacked one by one, may remain on each of the dummy active fin SF and the plurality of fin-type active regions F1 and F2.

The dummy active fin SF may be formed under the gate cut mask portion (the portion indicated by the dashed line P1 in FIG. 7) of the first mask pattern MP1, and the stack structure, in which the plurality of sacrificial semiconductor layers 104 and the plurality of nanosheet semiconductor layers NS are alternately stacked one by one, may remain between the dummy active fin SF and the gate cut mask portion.

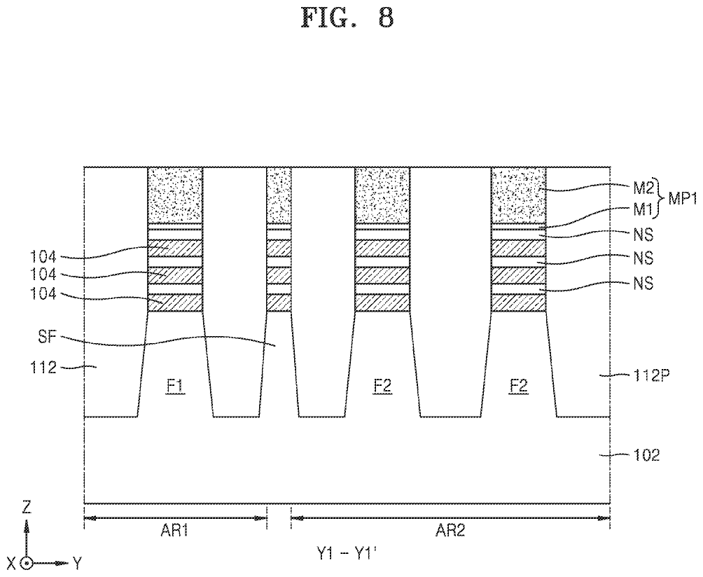

Referring to FIG. 8, in a resulting product of FIG. 7, a preliminary device isolation film 112P may be formed to fill spaces between the dummy active fin SF and the plurality of fin-type active regions F1 and F2 and to fill openings formed in the first mask pattern MP1, and a resulting product, in which the preliminary device isolation film 112P is formed, may be planarized by a chemical mechanical polishing (CMP) process, such that an upper surface of the preliminary device isolation film 112P is coplanar with an upper surface of the first mask pattern MP1. A constituent material of the preliminary device isolation film 112P is the same as described regarding the constituent material of the device isolation film 112 with reference to FIG. 2.

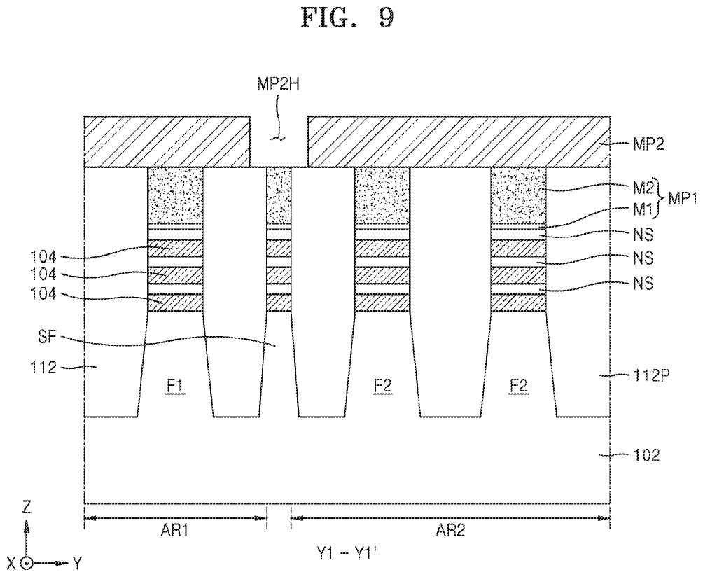

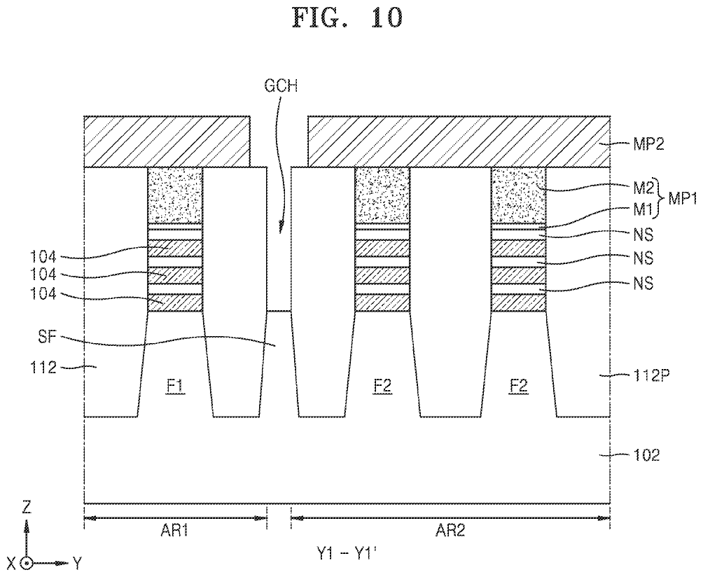

Referring to FIG. 9, a second mask pattern MP2 may be formed on a resulting product of FIG. 8. The second mask pattern MP2 may have an opening MP2H, which is arranged at a position overlapping the dummy active fin SF in the vertical direction (Z direction) to expose a portion of the first mask pattern MP1. FIG. 9 illustrates an example in which a portion of the first mask pattern MP1 and a portion of the preliminary device isolation film 112P therearound are exposed together by the opening MP2H of the second mask pattern MP2. However, the inventive concept is not limited to the example shown in FIG. 9. For example, the preliminary device isolation film 112P may not be exposed by the opening MP2H of the second mask pattern MP2, where the width in the second horizontal direction (Y direction) is the same as or less than the width of the underlying first mask pattern MP1 and vertically aligned with the first mask pattern MP1. In some embodiments, the second mask pattern MP2 may include, but is not limited to, an amorphous carbon layer (ACL) or a spin-on-hardmask (SOH).

Referring to FIG. 10, in a resulting product of FIG. 9, by using the second mask pattern MP2 as an etch mask, the first mask pattern MP1 exposed by the opening MP2H may be selectively removed, and the stack structure of the plurality of sacrificial semiconductor layers 104 and the plurality of nanosheet semiconductor layers NS, which remain on the dummy active fin SF, may be selectively removed, thereby forming a gate cut hole GCH. The upper surface of the dummy active fin SF may be exposed by the gate cut hole GCH.

To form the gate cut hole GCH, the stack structure of the plurality of sacrificial semiconductor layers 104 and the plurality of nanosheet semiconductor layers NS, which remain on each dummy active fin SF, may be selectively removed by using a liquid-phase or gas-phase etchant. In various embodiments, to selectively remove the stack structure of the plurality of sacrificial semiconductor layers 104 and the plurality of nanosheet semiconductor layers NS, which remain on each dummy active fin SF, a CH₃COOH-based etching solution, for example, an etching solution including a mixture of CH₃COOH, HNO₃, and HF, or an etching solution including a mixture of CH₃COOH, H₂O₂, and HF, may be used, but the inventive concept is not limited thereto.

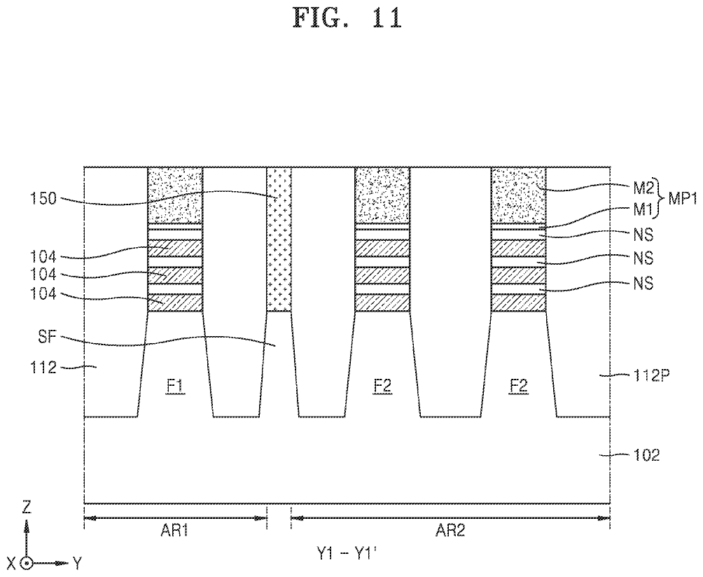

Referring to FIG. 11, a process of removing the second mask pattern MP2 and a process of forming the gate cut insulating pattern 150 to fill the gate cut hole GCH on the dummy active fin SF may be performed on a resulting product of FIG. 10. After the gate cut insulating pattern 150 is formed, a resulting product planarized for the upper surface of the gate cut insulating pattern 150, the upper surface of the preliminary device isolation film 112P, and the upper surface of the first mask pattern MP1 to be coplanar with each other may be obtained.

Referring to FIGS. 12A, 12B, and 12C, the device isolation film 112 having an upper surface reduced in height may be formed by performing a recess process of the preliminary device isolation film 112P on a resulting product of FIG. 11, and an upper surface of the uppermost nanosheet semiconductor layer NS from among the plurality of nanosheet semiconductor layers NS may be exposed by removing the first mask pattern MP1. A vertical level of an upper surface of the device isolation film 112 may be equal to or similar to the vertical level of the fin top surface FT of each of the plurality of fin-type active regions F1 and F2. A portion of the device isolation film 112 may remain covering the plurality of fin-type active regions F1 and F2 and the dummy active fin SF.

Referring to FIGS. 13A, 13B, 13C, and 13D, a plurality of dummy gate structures DGS, and the outer insulating spacer 118, which covers both sidewalls of each of the plurality of dummy gate structures DGS, may be formed on a resulting product of FIGS. 12A, 12B, and 12C. The plurality of dummy gate structures DGS may be formed to continuously extend lengthwise in the second horizontal direction (Y direction), at respective positions corresponding to the plurality of gate lines 160 shown in FIG. 1.

Each of the plurality of dummy gate structures DGS may have a structure in which an oxide film D112, a dummy gate layer D114, and a capping layer D116 are stacked in the stated order. In various embodiments, the dummy gate layer D114 may include a polysilicon film, and the capping layer D116 may include a silicon nitride film.

As shown in FIG. 13B, in the first device area AR1, each of the plurality of sacrificial semiconductor layers 104 and the plurality of nanosheet semiconductor layers NS may be partially removed by using a dummy gate structure DGS and the outer insulating spacer 118 as an etch mask, thereby forming the plurality of nanosheet stacks NSS from the plurality of nanosheet semiconductor layers NS. Each of the plurality of nanosheet stacks NSS may include, for example, the first to third nanosheets N1, N2, and N3. In the first device area AR1, a portion of the first fin-type active region F1, which is exposed between the plurality of nanosheet stacks NSS, may be etched, thereby forming a plurality of first recesses R1 in an upper portion of the first fin-type active region F1, where the first recesses R1 can be on opposite sides of a dummy gate structure DGS. To form the plurality of first recesses R1, the first fin-type active region F1 may be etched by dry etching, wet etching, or a combination thereof.

Next, in the first device area AR1, a plurality of indent regions 104D may be respectively formed between the first to third nanosheets N1, N2, and N3 and between the first nanosheet N1 and the first fin-type active region F1 by selectively removing portions of the plurality of sacrificial semiconductor layers 104, which are exposed on both sides of the nanosheet stack NSS by the plurality of first recesses R1, and then, the plurality of inner insulating spacers 120 may be formed to fill the plurality of indent regions 104D. To form the plurality of indent regions 104D, the portions of the plurality of sacrificial semiconductor layers 104 may be selectively etched by using a difference in etch selectivity between each of the plurality of sacrificial semiconductor layers 104 and each of the first to third nanosheets N1, N2, and N3. To form the plurality of inner insulating spacers 120, an atomic layer deposition (ALD) process, a chemical vapor deposition (CVD) process, an oxidation process, or a combination thereof may be used.

Next, the plurality of first source/drain regions SD1 may be formed on the first fin-type active region F1 on opposite sides of each of the plurality of nanosheet stacks NSS. To form the plurality of first source/drain regions SD1, a semiconductor material may be epitaxially grown on a surface of the first fin-type active region F1, which is exposed at bottom surfaces of the plurality of first recesses R1, and a sidewall of each of the first to third nanosheets N1, N2, and N3. In some embodiments, to form the plurality of first source/drain regions SD1, a low-pressure chemical vapor deposition (LPCVD) process, a selective epitaxial growth (SEG) process, or a cyclic deposition and etching (CDE) process may be performed by using source materials including an element semiconductor precursor. In some embodiments, the plurality of first source/drain regions SD1 may each include an Si layer doped with an n-type dopant. To form the plurality of first source/drain regions SD1, silane (SiH₄), disilane (Si₂H₆), trisilane (Si₃H₈), dichlorosilane (SiH₂Cl₂), or the like may be used. The n-type dopant may be selected from phosphorus (P), arsenic (As), and antimony (Sb).

As shown in FIG. 13C, in the second device area AR2, each of the plurality of sacrificial semiconductor layers 104 and the plurality of nanosheet semiconductor layers NS may be partially removed by using the dummy gate structure DGS and the outer insulating spacer 118 as an etch mask, thereby forming the plurality of nanosheet stacks NSS from the plurality of nanosheet semiconductor layers NS in the second device area AR2. Each of the plurality of nanosheet stacks NSS may include, for example, the first to third nanosheets N1, N2, and N3.

In the second device area AR2, the second fin-type active region F2, which is exposed between the plurality of nanosheet stacks NSS, may be etched, thereby forming a plurality of second recesses R2 in an upper portion of the second fin-type active region F2. Next, the plurality of second source/drain regions SD2 may be formed on the second fin-type active region F2 on both sides of the nanosheet stack NSS. Similar to the description made above regarding the process of forming the plurality of first source/drain regions SD1, to form the plurality of second source/drain regions SD2, a semiconductor material may be epitaxially grown on a surface of the second fin-type active region F2, which is exposed at bottom surfaces of the plurality of second recesses R1, and the sidewall of each of the first to third nanosheets N1, N2, and N3. In some embodiments, the plurality of second source/drain regions SD2 may each include an SiGe layer doped with a p-type dopant. To form the plurality of second source/drain regions SD2, an Si source and a Ge source may be used. As the Si source, silane (SiH₄), disilane (Si₂H₆), trisilane (Si₃H₈), dichlorosilane (SiH₂Cl₂), or the like may be used. As the Ge source, germane (GeH₄), digermane (Ge₂H₆), trigermane (Ge₃H₈), tetragermane (Ge₄H₁₀), dichlorogermane (Ge₂H₂Cl₂), or the like may be used. The p-type dopant may be selected from boron (B) and gallium (Ga).

Respective sequences of the process of forming the plurality of first source/drain regions SD1 in the first device area AR1 and the process of forming the plurality of second source/drain regions SD2 in the second device area AR2 may be arbitrarily determined. In some embodiments, each of the plurality of first source/drain regions SD1 and each of the plurality of second source/drain regions SD2 may include the same material. In this case, the process of forming the plurality of first source/drain regions SD1 and the process of forming the plurality of second source/drain regions SD2 may be simultaneously performed.

As shown in FIG. 13D, the gate cut insulating pattern 150 can be on the dummy active fin SF, and a portion of the dummy gate structure DGS and outer insulating spacers 118 can be across the gate cut insulating pattern 150. The gate cut insulating pattern 150 and dummy active fin SF can each extend laterally to either side of the dummy gate structure DGS.

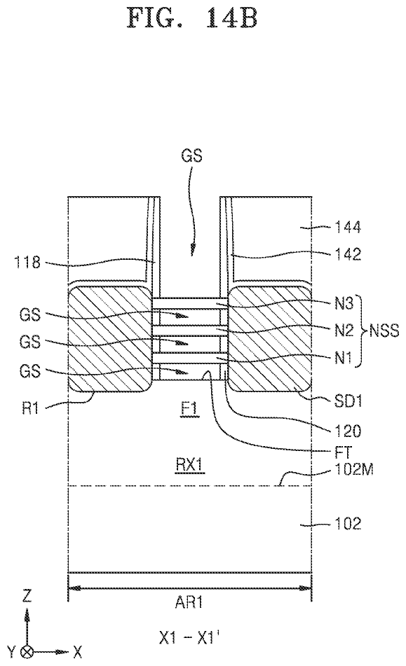

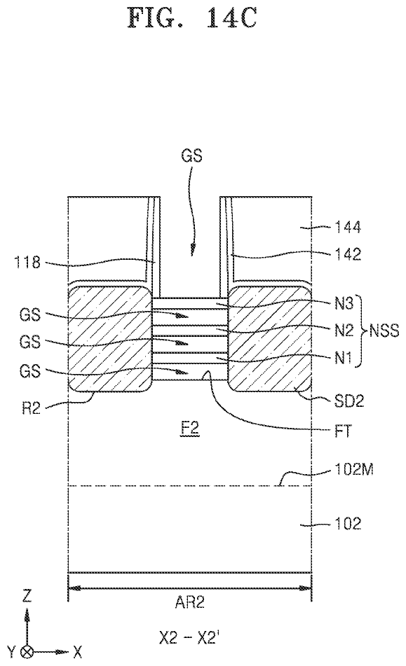

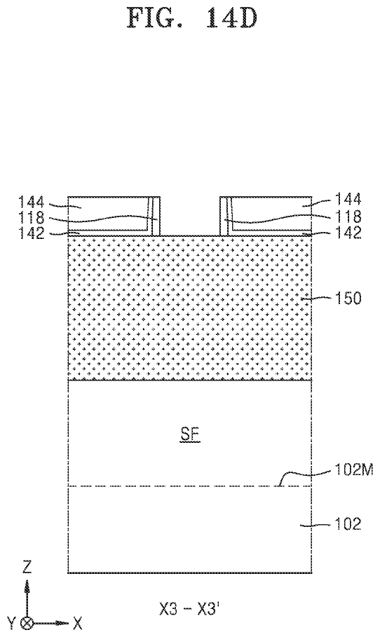

Referring to FIGS. 14A, 14B, 14C, and 14D, in a resulting product of FIGS. 13A, 13B, 13C, and 13D, the insulating liner 142 may be formed to cover a surface of each of the first and second source/drain regions SD1 and SD2 and a surface of each of the plurality of outer insulating spacers 118, and the inter-gate dielectric 144 may be formed on the insulating liner 142. The capping layer D116 may be removed, and the plurality of outer insulating spacers 118, the insulating liner 142, and the inter-gate dielectric 144 may be planarized, thereby exposing an upper surface of the dummy gate layer D114.

A plurality of gate spaces GS may be provided by removing the exposed dummy gate layer D114 and the oxide film D112 thereunder, and the plurality of nanosheet stacks NSS may be exposed by the plurality of gate spaces GS. By removing the plurality of sacrificial semiconductor layers 104 remaining on an obtained resulting product through a gate space GS, each of the plurality of gate spaces GS may expand up to each space between the first nanosheet N1, the second nanosheet N2, and the third nanosheet N3 and a space between the first nanosheet N1 and the fin top surface FT. In various embodiments, to selectively remove the plurality of sacrificial semiconductor layers 104, a difference in etch selectivity between each of the first nanosheet N1, the second nanosheet N2, and the third nanosheet N3 and each of the plurality of sacrificial semiconductor layers 104 may be used.

To selectively remove the plurality of sacrificial semiconductor layers 104, a liquid-phase or gas-phase etchant may be used. In some embodiments, to selectively remove the plurality of sacrificial semiconductor layers 104, a CH₃COOH-based etching solution, for example, an etching solution including a mixture of CH₃COOH, HNO₃, and HF, or an etching solution including a mixture of CH₃COOH, H₂O₂, and HF, may be used, but the inventive concept is not limited thereto.

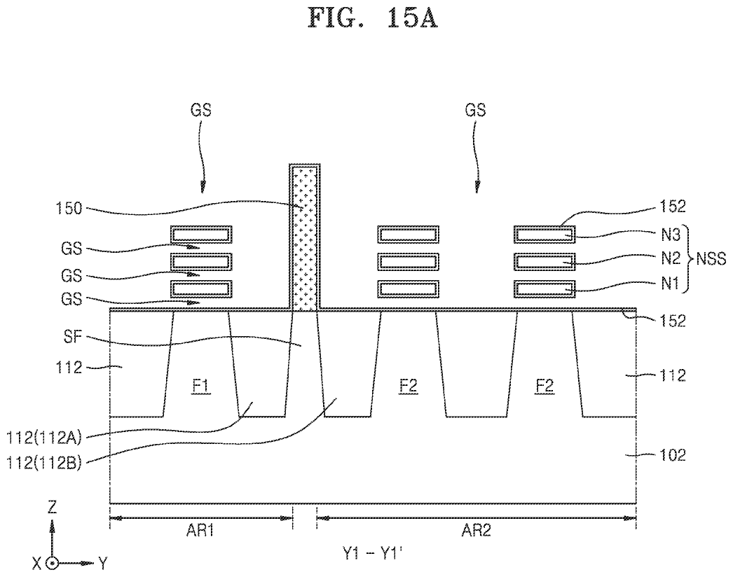

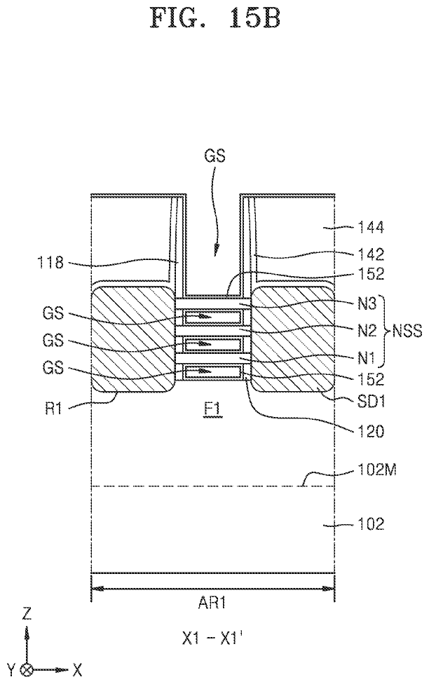

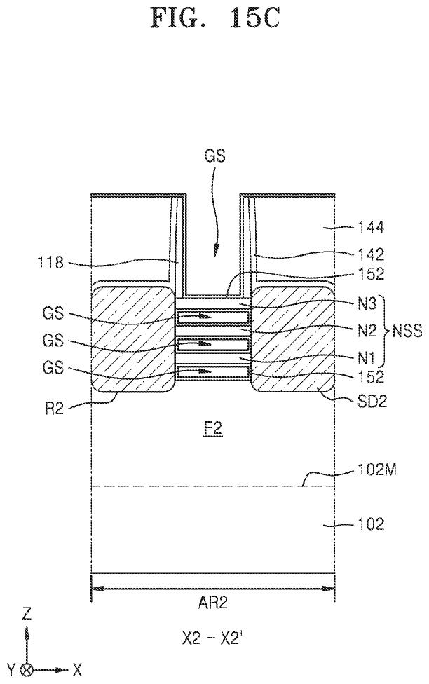

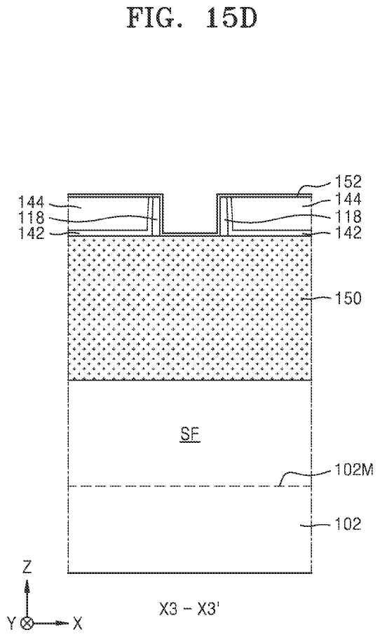

Referring to FIGS. 15A, 15B, 15C, and 15D, in a resulting product of FIGS. 14A, 14B, 14C, and 14D, the gate dielectric film 152 may be formed to cover exposed surfaces. The gate dielectric film 152 may include a portion covering respective exposed surfaces of the first nanosheet N1, the second nanosheet N2, and the third nanosheet N3, a portion covering respective exposed surfaces of the plurality of fin-type active regions F1 and F2, a portion covering exposed surfaces of the gate cut insulating pattern 150, and a portion covering exposed surfaces of the device isolation film 112. To form the gate dielectric film 152, an ALD process may be used.

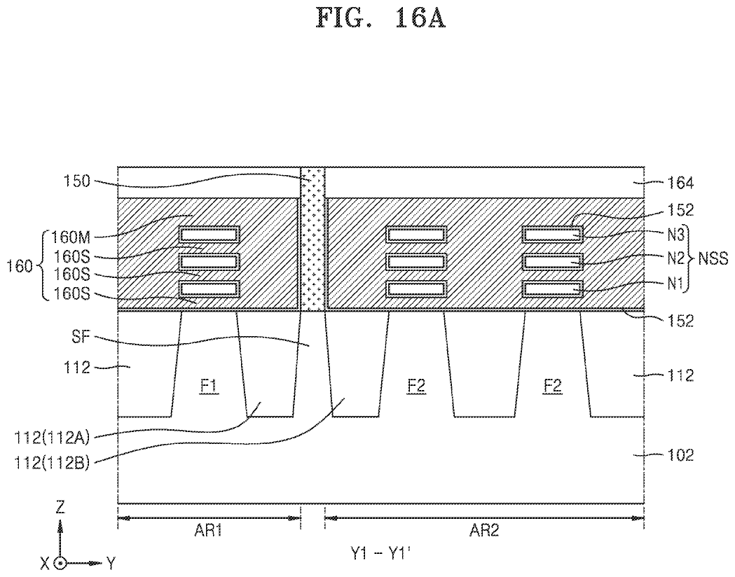

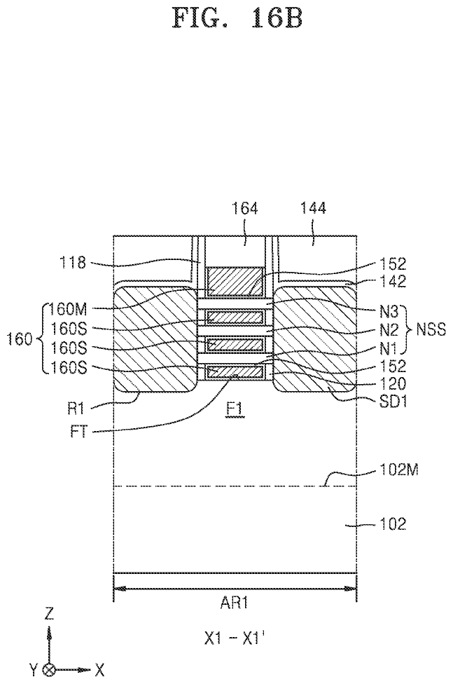

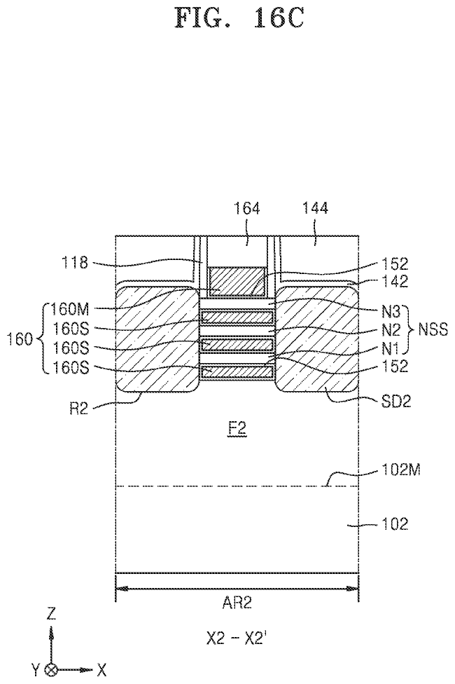

Referring to FIGS. 16A, 16B, and 16C, the gate line 160 may be formed on the gate dielectric film 152 to fill the plurality of gate spaces GS (see FIGS. 15A, 15B, and 15C), followed by partially removing each of the gate dielectric film 152 and the gate line 160 such that a portion of each of the plurality of gate spaces GS (see FIGS. 15A, 15B, and 15C) on the gate dielectric film 152 is emptied again, and then, the capping insulating pattern 164 may be formed to cover the upper surface of each of the gate line 160 and the gate dielectric film 152 in the gate space GS remaining on the gate dielectric film 152 and the gate line 160.

A resulting product, in which the capping insulating pattern 164 is formed, may be planarized such that the upper surface of the gate cut insulating pattern 150 is coplanar with the upper surface of the capping insulating pattern 164. After the capping insulating pattern 164 is formed, the upper surface of the gate cut insulating pattern 150 may be exposed. The capping insulating pattern 164 may include a portion contacting an upper sidewall of the gate cut insulating pattern 150.

Next, as shown in FIGS. 2A to 2D, in the first device area AR1 and the second device area AR2, a plurality of holes may be formed to expose portions of the first and second source/drain regions SD1 and SD2 by partially removing each of the inter-gate dielectric 144 and the insulating liner 142, followed by forming the metal silicide film 172 on the first and second source/drain regions SD1 and SD2 via the plurality of holes, and then, the plurality of source/drain contacts 174 may be formed to respectively fill the plurality of holes. The insulating structure 190 may be formed by forming the etch stop film 190A and the interlayer dielectric 190B in the stated order on a resulting product in which the plurality of source/drain contacts 174 are formed, and the plurality of source/drain via contacts 192 may be formed to pass through the insulating structure 190 in the vertical direction (Z direction), thereby fabricating the integrated circuit device 100.

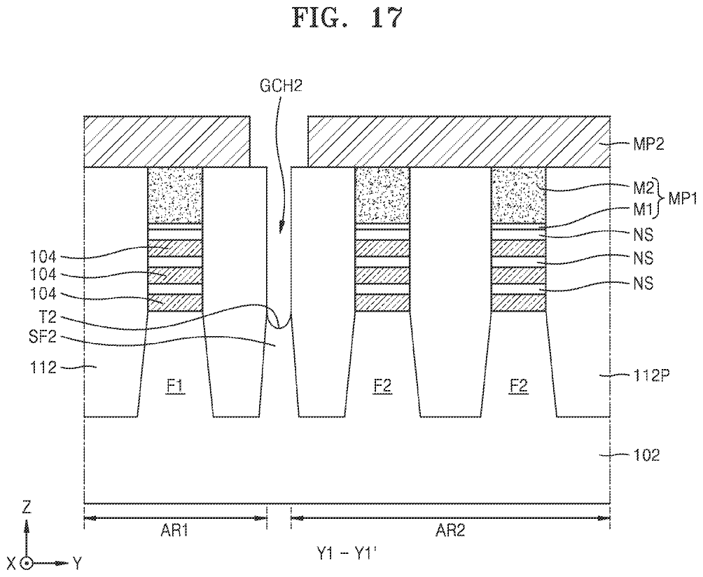

FIG. 17 is a cross-sectional view illustrating a method of fabricating an integrated circuit device, according to some embodiments. FIG. 17 illustrates some components in a region corresponding to a cross-section taken along the line Y1-Y′ of FIG. 1. An example of a method of fabricating the integrated circuit device 200 shown in FIG. 3 is described with reference to FIG. 17. In FIG. 17, the same reference numerals as in FIGS. 1 to 16C respectively denote the same members, and here, repeated descriptions thereof are omitted.

Referring to FIG. 17, to fabricate the integrated circuit device 200 shown in FIG. 3, similar processes to the descriptions made with reference to FIGS. 6 to 16C may be performed. However, after the gate cut hole GCH is formed to expose the upper surface of the dummy active fin SF in the process described with reference to FIG. 10, the gate cut hole GCH may be expanded more toward the substrate 102 by wet-etching a portion of the dummy active fin SF, which is exposed by the gate cut hole GCH, thereby forming a gate cut hole GCH2. As a result, in the gate cut hole GCH2, the dummy active fin SF2, which is a modified result of the dummy active fin SF, may be obtained. The dummy active fin SF2 may have a concave upper surface T2 toward the gate cut hole GCH2.

Next, in a similar manner to the description made with reference to FIG. 11, the gate cut insulating pattern 250 (see FIG. 3) may be formed to fill the gate cut hole GCH2, and the processes described with reference to FIGS. 12A to 16C may be performed, thereby fabricating the integrated circuit device 200 shown in FIG. 3.

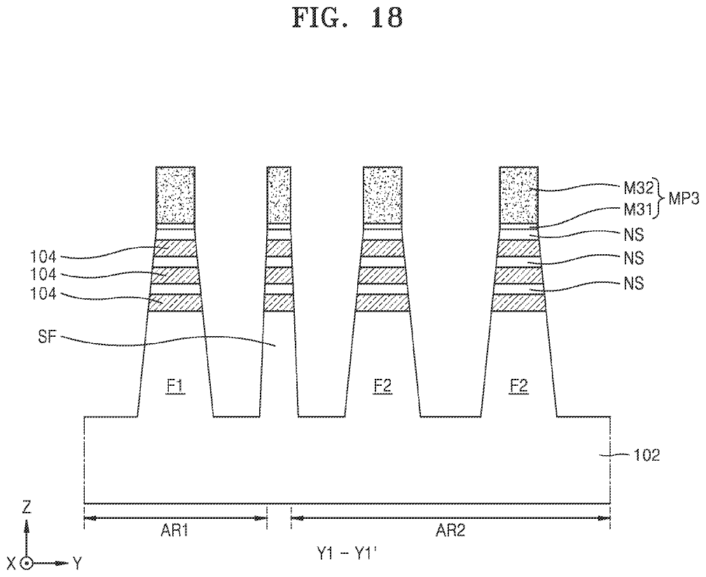

FIG. 18 is a cross-sectional view illustrating a method of fabricating an integrated circuit device, according to some embodiments. FIG. 18 illustrates some components in a region corresponding to a cross-section taken along the line Y1-Y1′ of FIG. 1. An example of a method of fabricating the integrated circuit device 300 shown in FIG. 4 is described with reference to FIG. 18. In FIG. 18, the same reference numerals as in FIGS. 1 to 16C respectively denote the same members, and here, repeated descriptions thereof are omitted.

Referring to FIG. 18, to fabricate the integrated circuit device 300 shown in FIG. 4, similar processes to the descriptions made with reference to FIGS. 6 to 16C may be performed. However, in the process described with reference to FIG. 7, a portion of each of the plurality of sacrificial semiconductor layers 104, the plurality of nanosheet semiconductor layers NS, and the substrate 102 may be etched by using a mask pattern MP3, instead of the first mask pattern MP1, as an etch mask. The mask pattern MP3 may include a double-layer structure of a silicon oxide film M31 and a silicon nitride film M32. Here, by controlling an etching atmosphere during the process of etching the plurality of sacrificial semiconductor layers 104 and the plurality of nanosheet semiconductor layers NS, a sidewall of each stack structure of the plurality of sacrificial semiconductor layers 104 and the plurality of nanosheet semiconductor layers NS, which remain on each of the dummy active fin SF and the plurality of fin-type active regions F1 and F2, may form an inclined surface, and each stack structure thereof may have an increasing width in the second horizontal direction (Y direction) with a decreasing distance from the substrate 102. Next, the integrated circuit device 300 shown in FIG. 4 may be fabricated by performing the processes described with reference to FIGS. 8 to 16C.

Heretofore, although the examples of the methods of fabricating the integrated circuit devices 100, 200, and 300 haven been described with reference to FIGS. 6 to 18, it will be understood by those of ordinary skill in the art that, by making various modifications and changes to the examples described with reference to FIGS. 6 to 18 without departing from the spirit and scope of the inventive concept, the integrated circuit device 400 shown in FIG. 5 or integrated circuit devices having various structures modified and changed therefrom may be fabricated.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a first fin-type active region and a second fin-type active region, which extend parallel to each other in a first horizontal direction on a substrate and are spaced apart from each other in a second horizontal direction intersecting with the first horizontal direction;
a device isolation film adjacent to each of the first fin-type active region and the second fin-type active region;
a first gate line arranged on the first fin-type active region and extending lengthwise in the second horizontal direction;
a second gate line arranged on the second fin-type active region and separated from the first gate line in the second horizontal direction, the second gate line extending lengthwise along an extension line of the first gate line in the second horizontal direction; and
a gate cut insulating pattern between the first gate line and the second gate line,
wherein the device isolation film comprises a first local isolation portion and a second local isolation portion, which are arranged between the first fin-type active region and the second fin-type active region, the first local isolation portion and the second local isolation portion being apart from each other in the second horizontal direction with the gate cut insulating pattern therebetween.

2. The integrated circuit device of claim 1, further comprising a dummy active fin arranged between the first local isolation portion and the second local isolation portion and between the substrate and the gate cut insulating pattern,
wherein the dummy active fin comprises the same material as at least one of the first fin-type active region and the second fin-type active region.

3. The integrated circuit device of claim 1, further comprising:
a first nanosheet stack arranged over the first fin-type active region and comprising at least one nanosheet surrounded by the first gate line; and
a second nanosheet stack arranged over the second fin-type active region and comprising at least one nanosheet surrounded by the second gate line,
wherein a vertical level of an upper surface of the gate cut insulating pattern is farther from the substrate than a vertical level of an upper surface of each of the first nanosheet stack and the second nanosheet stack.

4. The integrated circuit device of claim 1, wherein a vertical level of an upper surface of the gate cut insulating pattern is farther from the substrate than a vertical level of an upper surface of each of the first gate line and the second gate line.

5. The integrated circuit device of claim 1, wherein a lower surface of the gate cut insulating pattern is on an extension line of a fin top surface of at least one of the first fin-type active region and the second fin-type active region in the second horizontal direction.

6. The integrated circuit device of claim 1, wherein a lower surface of the gate cut insulating pattern is closer to the substrate than a fin top surface of at least one of the first fin-type active region and the second fin-type active region.

7. The integrated circuit device of claim 1, wherein the gate cut insulating pattern has a first sidewall facing the first gate line, and a second sidewall facing the second gate line.

8. The integrated circuit device of claim 1, wherein the gate cut insulating pattern has a first sidewall, which faces the first gate line, and a second sidewall, which faces the second gate line,
each of the first sidewall and the second sidewall of the gate cut insulating pattern comprises a portion extending in an inclined direction with respect to a direction perpendicular to a main surface of the substrate with an increasing distance from the substrate, and
a width of the gate cut insulating pattern in the second horizontal direction gradually decreases away from the substrate.

9. The integrated circuit device of claim 1, further comprising a gate dielectric film contacting a sidewall of the gate cut insulating pattern.

10. The integrated circuit device of claim 1, wherein the gate cut insulating pattern comprises a lower extension portion that is closer to the substrate than a vertical level of an upper surface of the device isolation film, and
a lower surface of the lower extension portion has a convex shape toward the substrate.

11. The integrated circuit device of claim 1, further comprising a dummy active fin arranged between the first local isolation portion and the second local isolation portion to protrude from the substrate toward the gate cut insulating pattern and vertically overlapping the gate cut insulating pattern,
wherein the dummy active fin extends parallel to the first fin-type active region and the second fin-type active region, between the first fin-type active region and the second fin-type active region.

12. The integrated circuit device of claim 1, wherein the device isolation film further comprises an inter-active-region device isolation film between an adjacent pair of the first fin-type active regions in the first fin-type active region or between an adjacent pair of the second fin-type active regions in the second fin-type active region, or both, and
a width of each of the first local isolation portion and the second local isolation portion is less in the second horizontal direction than the width of the inter-active-region device isolation film.

13. The integrated circuit device of claim 1, wherein the gate cut insulating pattern comprises silicon nitride (SiN), SiCN, SiON, SiOCN, SiBN, SiBCN, SiOC, SiC, or a combination thereof.

14. An integrated circuit device comprising:
a plurality of fin-type active regions protruding in a vertical direction from a substrate and extending parallel to each other in a first horizontal direction, the plurality of fin-type active regions being spaced apart from each other in a second horizontal direction that intersects with the first horizontal direction;
a device isolation film adjacent to the plurality of fin-type active regions;
a plurality of first gate lines extending lengthwise in the second horizontal direction on the plurality of fin-type active regions;
a plurality of second gate lines separated from the plurality of first gate lines in the second horizontal direction by a dummy active fin between a first fin-type active region and a second fin-type active region, wherein the dummy active fin protrudes in the vertical direction from the substrate and extends lengthwise in the first horizontal direction; and
a gate cut insulating pattern extending lengthwise in the first horizontal direction between the plurality of first gate lines and the plurality of second gate lines and overlapping the dummy active fin in the vertical direction,
wherein the device isolation film comprises a first local isolation portion between the first fin-type active region and the dummy active fin and a second local isolation portion between the second fin-type active region and the dummy active fin.

15. The integrated circuit device of claim 14, wherein the dummy active fin and the plurality of fin-type active regions are integrally connected to the substrate.

16. The integrated circuit device of claim 14, further comprising a plurality of nanosheet stacks arranged over each of the plurality of fin-type active regions, each of the plurality of nanosheet stacks comprising at least one nanosheet surrounded by one gate line selected from the plurality of first gate lines and the plurality of second gate lines,
wherein a vertical level of an upper surface of the gate cut insulating pattern is farther from the substrate than a vertical level of an upper surface of each of the plurality of first gate lines and the plurality of second gate lines.

17. The integrated circuit device of claim 14, wherein a vertical level of a lower surface of the gate cut insulating pattern is closer to the substrate than a vertical level of a lower surface of each of the plurality of first gate lines and the plurality of second gate lines.

18. The integrated circuit device of claim 14, wherein a vertical level of a lower surface of the gate cut insulating pattern is closer to the substrate than a vertical level of a fin top surface of each of the plurality of fin-type active regions.

19. The integrated circuit device of claim 14, wherein the gate cut insulating pattern comprises sidewalls extending in an inclined direction with respect to a direction perpendicular to a main surface of the substrate and facing the plurality of first gate lines and the plurality of second gate lines,
a width of the gate cut insulating pattern in the second horizontal direction gradually decreases away from the substrate,
a lower surface of the gate cut insulating pattern is closer to the substrate than a vertical level of a fin top surface of each of the plurality of fin-type active regions, and
an upper surface of the dummy active fin is closer to the substrate than the vertical level of the fin top surface of each of the plurality of fin-type active regions.

20. An integrated circuit device comprising:
a first fin-type active region and a second fin-type active region, which protrude in a vertical direction from a substrate and are adjacent to each other;
a device isolation film covering both sidewalls of each of the first fin-type active region and the second fin-type active region;
a first nanosheet stack, including at least one nanosheet, arranged over the first fin-type active region;
a first gate line surrounding the first nanosheet stack;
a second nanosheet stack, including at least one nanosheet, arranged over the second fin-type active region;
a second gate line surrounding the second nanosheet stack;
a dummy active fin separating the first fin-type active region from the second fin-type active region and protruding in the vertical direction from the substrate;
a gate cut insulating pattern separating the first gate line from the second gate line, wherein the gate cut insulating pattern is on the dummy active fin in the vertical direction, and the gate cut insulating pattern extends above the first gate line and the second gate line;
a first gate dielectric film separating the at least one nanosheet of the first nanosheet stack from the first gate line, wherein the first gate dielectric film contacts a first sidewall of the gate cut insulating pattern; and
a second gate dielectric film separating the at least one nanosheet of the second nanosheet stack from the second gate line, wherein the second gate dielectric film contacts a second sidewall of the gate cut insulating pattern opposite the first sidewall,
wherein the device isolation film comprises a first local isolation portion between the first fin-type active region and the dummy active fin, and a second local isolation portion between the second fin-type active region and the dummy active fin.
